(19) United States
(12) Patent Application Publication
(10) Pub. No.: US 2025/0233099 A1
(43) Pub. Date: Jul. 17, 2025

(54) SEMICONDUCTOR DEVICE AND METHOD FOR MANUFACTURING SEMICONDUCTOR DEVICE

(71) Applicant: Rohm Co., Ltd., Kyoto-shi (JP)

(72) Inventor: Ryosuke FUKUDA, Kyoto-shi (JP)

(21) Appl. No.: 19/098,531

(22) Filed: Apr. 2, 2025

(30) Foreign Application Priority Data
Oct. 12, 2022 (JP) 2022-164111

(51) Int. Cl. H01L 23/00; H01L 21/48; H01L 23/31; H01L 23/495; H01L 25/07

(52) U.S. Cl. CPC H01L 24/40; H01L 21/4825; H01L 23/49558; H01L 23/49575; H01L 25/072; H01L 23/3107; H01L 24/32; H01L 24/73; H01L 2224/32245; H01L 2224/40137; H01L 2224/40247; H01L 2224/73263

(57) ABSTRACT

A semiconductor device includes a semiconductor circuit section, a first conductive member electrically conducting to the semiconductor circuit section, a second conductive member electrically conducting to the semiconductor circuit section, an insulating member in contact with the first conductive member and the second conductive member, and a sealing resin covering the semiconductor circuit section, the first conductive member, the second conductive member, and a portion of the insulating member. The first conductive member and the second conductive member are fixed together by the insulating member.

### TECHNICAL FIELD

The present disclosure relates to a semiconductor device and a method for manufacturing a semiconductor device.

### BACKGROUND ART

Semiconductor devices in which semiconductor elements, such as diodes or transistors, are covered with a resin package are conventionally known (e.g., JP-A-2021-166215). The semiconductor device disclosed in JP-A-2021-166215 includes a first to a third lead frames, power semiconductor chips, a first inner lead, a second inner lead, and a molding resin. The power semiconductor chips include a first power semiconductor chip bonded to the first lead frame and a second power semiconductor chip bonded to the second lead frame. The first and the second power semiconductor chips each have the function of a switching element. The first inner lead connects the first power semiconductor chip and the second lead frame. The second inner lead connects the second power semiconductor chip and the third lead frame. In the manufacturing process of such a semiconductor device, the two inner leads are disposed individually.

### BRIEF DESCRIPTION OF THE DRAWINGS

FIG. 1 is a perspective view of a semiconductor device according to a first embodiment.

FIG. 2 is a plan view of the semiconductor device according to the first embodiment.

FIG. 3 is a plan view corresponding to FIG. 2, in which a sealing resin is indicated by imaginary lines.

FIG. 4 is a partial enlarged view in which a portion of FIG. 3 is enlarged.

FIG. 5 is a bottom view of the semiconductor device according to the first embodiment.

FIG. 6 is a front view of the semiconductor device according to the first embodiment.

FIG. 7 is a right side view of the semiconductor device according to the first embodiment.

FIG. 8 is a partial enlarged view in which a portion of FIG. 7 is enlarged and the sealing resin is indicated by imaginary lines.

FIG. 9 is a sectional view taken along line IX-IX in FIG. 3.

FIG. 10 is a partial enlarged view in which a portion of FIG. 9 is enlarged.

FIG. 11 is a partial enlarged view in which a portion of FIG. 9 is enlarged.

FIG. 12 is a partial enlarged view in which a portion of FIG. 9 is enlarged.

FIG. 13 is a sectional view taken along line XIII-XIII in FIG. 3.

FIG. 14 is a partial enlarged view in which a portion of FIG. 13 is enlarged.

FIG. 15 is a sectional view taken along line XV-XV in FIG. 3.

FIG. 16 is a sectional view taken along line XVI-XVI in FIG. 3.

FIG. 17 is a diagram showing an example of circuit configuration of the semiconductor device according to the first embodiment.

FIG. 18 is a plan view showing a step of a method for manufacturing the semiconductor device according to the first embodiment.

FIG. 19 is a plan view showing a step of the method for manufacturing the semiconductor device according to the first embodiment.

FIG. 20 is a sectional view showing a step of the method for manufacturing the semiconductor device according to the first embodiment.

FIG. 21 is a plan view view showing a semiconductor device according to a first variation of the first embodiment, in which the sealing resin is indicated by imaginary lines.

FIG. 22 is a diagram showing an example of circuit configuration of the semiconductor device according to the first variation of the first embodiment.

FIG. 23 is a plan view view showing a semiconductor device according to a second variation of the first embodiment, in which the sealing resin is indicated by imaginary lines.

FIG. 24 is a diagram showing an example of circuit configuration of the semiconductor device according to the second variation of the first embodiment.

FIG. 25 is a plan view view showing a semiconductor device according to a third variation of the first embodiment, in which the sealing resin is indicated by imaginary lines.

FIG. 26 is a diagram showing an example of circuit configuration of the semiconductor device according to a third variation of the first embodiment.

FIG. 27 is a plan view view showing a semiconductor device according to a second embodiment, in which the sealing resin is indicated by imaginary lines.

FIG. 28 is a partial enlarged view in which a portion of FIG. 27 is enlarged.

FIG. 29 is a sectional view taken along line XXIX-XXIX in FIG. 27.

FIG. 30 is a diagram showing an example of circuit configuration of the semiconductor device according to the second embodiment.

FIG. 31 is a plan view view showing a semiconductor device according to a first variation of the second embodiment, in which the sealing resin is indicated by imaginary lines.

FIG. 32 is a plan view view showing a semiconductor device according to a second variation of the second embodiment, in which the sealing resin is indicated by imaginary lines.

FIG. 33 is a plan view view showing a semiconductor device according to a third variation of the second embodiment, in which the sealing resin is indicated by imaginary lines.

FIG. 34 is a sectional view corresponding to FIG. 13, showing a semiconductor device according to a variation.

FIG. 35 is a sectional view corresponding to FIG. 13, showing a semiconductor device according to a variation.

FIG. 36 is an enlarged plan view showing a main part of a semiconductor device according to a variation.

FIG. 37 is a sectional view corresponding to FIG. 9, showing the semiconductor device of FIG. 36.

FIG. 38 is an enlarged plan view showing a main part of a semiconductor device according to a variation.

FIG. 39 is a sectional view corresponding to FIG. 13, showing a semiconductor device according to a variation.

FIG. 40 is an enlarged plan view showing a main part of a semiconductor device according to a variation.

FIG. 41 is a front view showing the semiconductor device of FIG. 40, in which the sealing resin is indicated by imaginary lines.

### DETAILED DESCRIPTION OF EMBODIMENTS

The following describes preferred embodiments of the present disclosure in detail with reference to the drawings. Hereinafter, the same or similar elements are denoted by the same reference signs, and repeated description thereof is omitted. In the present disclosure, the terms such as “first”, “second”, and “third” are used merely as labels and are not intended to impose ordinal requirements on the items to which these terms refer.

In the description of the present disclosure, the expression “An object A is formed in an object B”, and “An object A is formed on an object B” imply the situation where, unless otherwise specifically noted, “the object A is formed directly in or on the object B”, and “the object A is formed in or on the object B, with something else interposed between the object A and the object B”. Likewise, the expression “An object A is disposed in an object B”, and “An object A is disposed on an object B” imply the situation where, unless otherwise specifically noted, “the object A is disposed directly in or on the object B”, and “the object A is disposed in or on the object B, with something else interposed between the object A and the object B”. Further, the expression “An object A is located on an object B” implies the situation where, unless otherwise specifically noted, “the object A is located on the object B, in contact with the object B”, and “the object A is located on the object B, with something else interposed between the object A and the object B”. Still further, the expression “An object A overlaps with an object B as viewed in a certain direction” implies the situation where, unless otherwise specifically noted, “the object A overlaps with the entirety of the object B”, and “the object A overlaps with a part of the object B”. In addition, the expression “An object A (or its material) contains a certain material C” includes the situation where “the object A (or its material) is made of the material C” and the situation where “the main component of the object A (or its material) is the material C”.

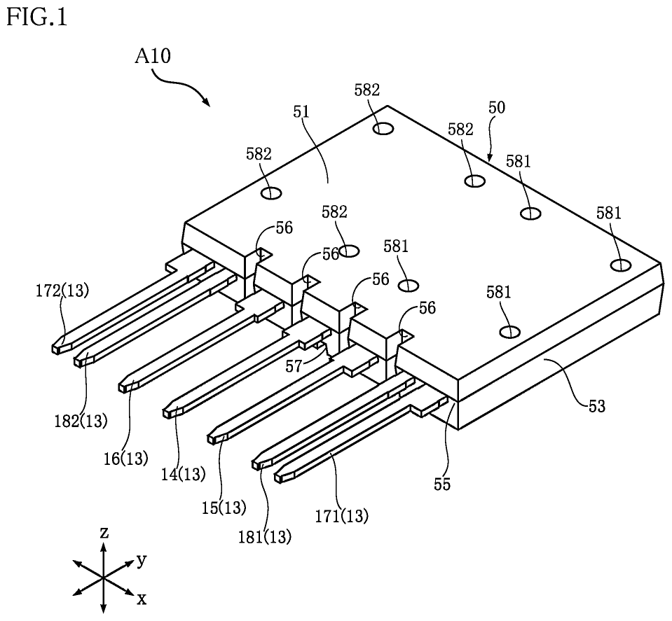

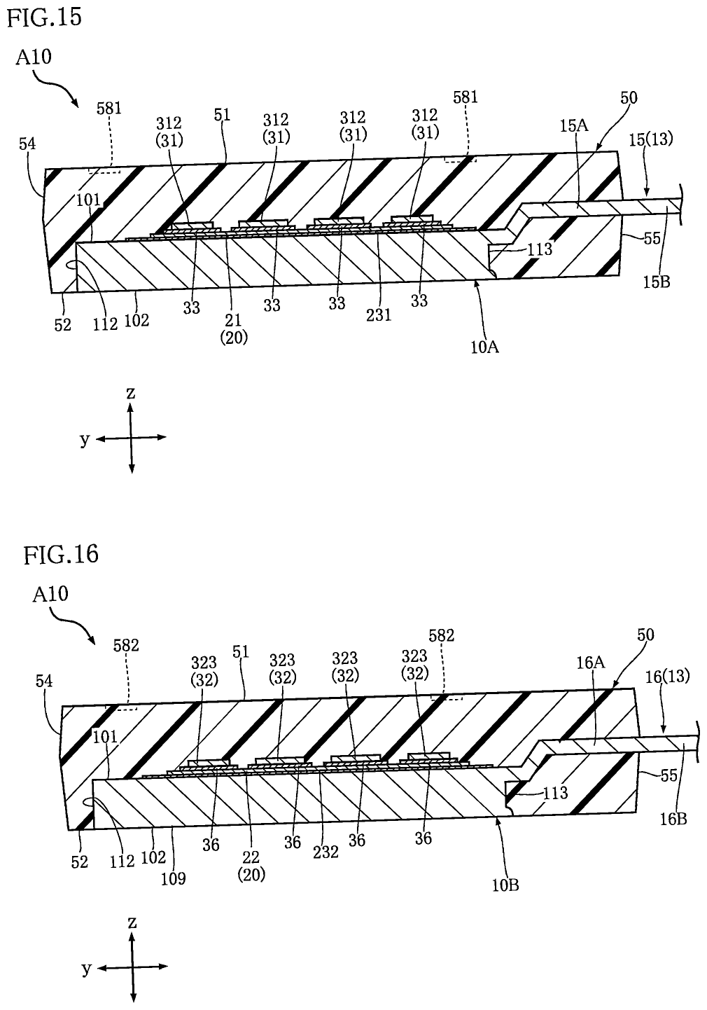

FIGS. 1 to 17 show a semiconductor device A10 according to a first embodiment. The semiconductor device A10 includes a first mount portion 10A, a second mount portion 10B, a plurality of terminal leads 13, a semiconductor circuit section 20, two conductive members 31 and 32, a plurality of conductive members 41A, 41B, 42A, and 42B, a sealing resin 50, and an insulating member 60. The plurality of terminal leads 13 include a first terminal lead 14, a second terminal lead 15, a third terminal lead 16, a fourth terminal lead 171, a sixth terminal lead 172, a fifth terminal lead 181, and a seventh terminal lead 182. The semiconductor circuit section 20 includes a first chip 21 and a second chip 22.

For the convenience of description, the thickness direction of the semiconductor device A10 is referred to as the “thickness direction z”. In the following description, one side in the thickness direction z may be referred to as the upper side, and the other side as the lower side. Note that the terms such as “upper”, “lower”, “upper side”, “lower side”, “upper surface” and “lower surface” indicate the relative positional relationship of parts or the like in the thickness direction z, and do not necessarily define the relationship with respect to the direction of gravity. In addition, “in plan view” means as viewed in the thickness direction z. A direction orthogonal to the thickness direction z is referred to as the “first direction x”. The direction orthogonal to the thickness direction z and the first direction x is referred to as the “second direction y”.

The semiconductor device A10 converts the DC power supply voltage applied to the first terminal lead 14 and the second terminal lead 15 of the plurality of terminal leads 13 into AC voltage by using the semiconductor circuit section 20 (the first chip 21 and the second chip 22). The converted AC voltage is inputted to a power supply target, such as a motor, through the third terminal lead 16 of the plurality of terminal leads 13. The semiconductor device A10 is used in a power conversion circuit, such as an inverter.

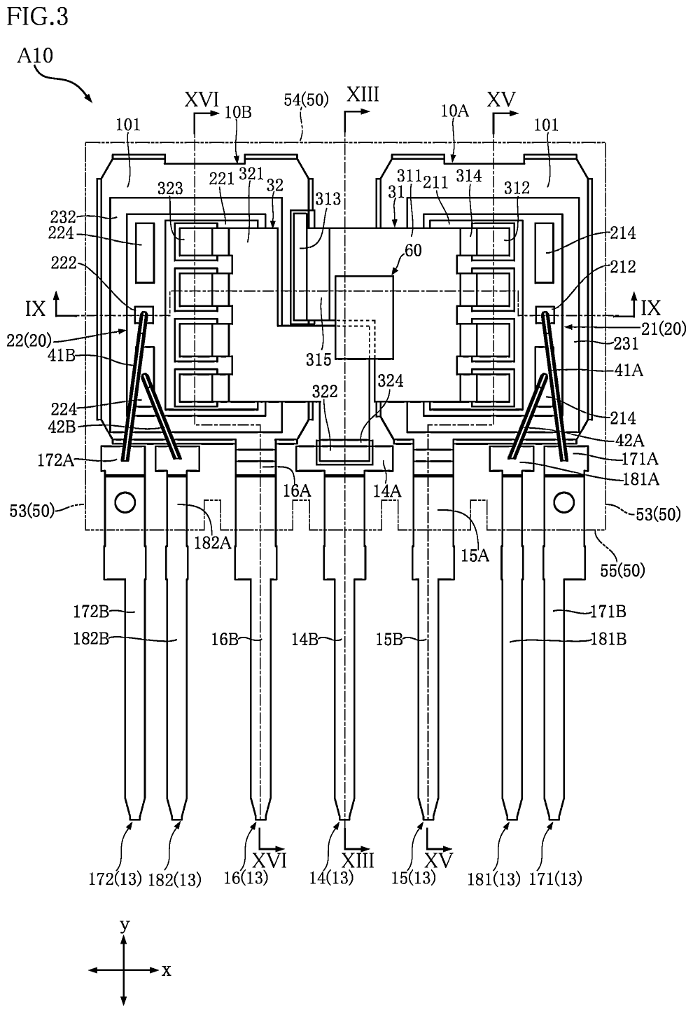

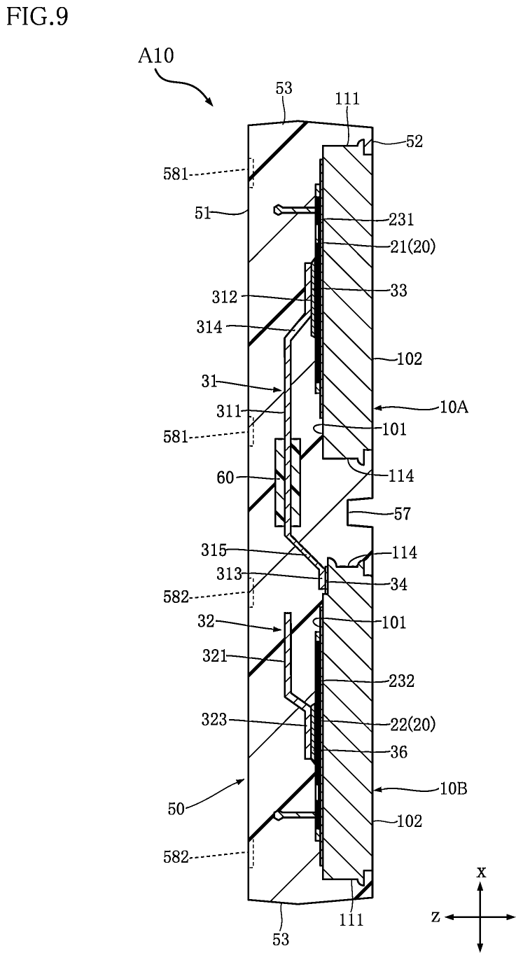

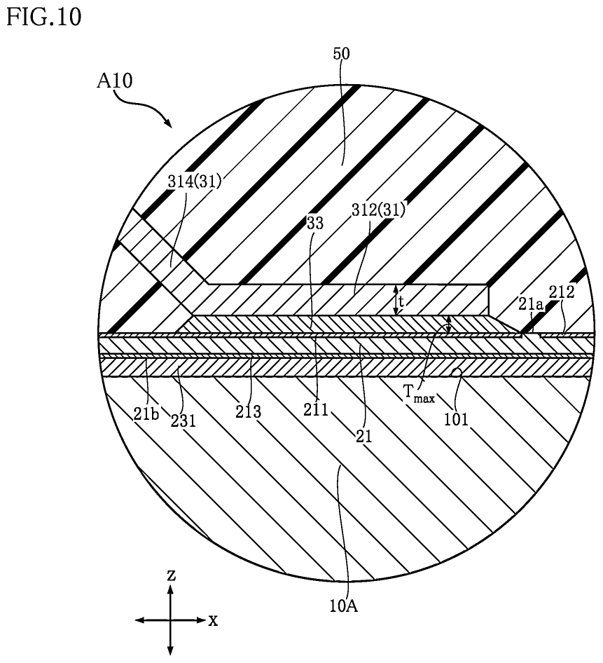

As shown in FIGS. 3 and 9, the first mount portion 10A and the second mount portion 10B are spaced apart from each other in the first direction x. The first mount portion 10A, the second mount portion 10B, and the terminal leads 13 are formed from the same lead frame. The lead frame is made of copper (Cu) or a copper alloy. Thus, the composition of the first mount portion 10A, the second mount portion 10B, and the terminal leads 13 includes copper. Each of the first mount portion 10A and the second mount portion 10B is, for example, generally rectangular in plan view.

As shown in FIG. 9, each of the first mount portion 10A and the second mount portion 10B has an obverse surface 101 and a reverse surface 102. Unless otherwise specified, the obverse surface 101 and the reverse surface 102 described below are common to the first mount portion 10A and the second mount portion 10B. The obverse surface 101 faces one side (the upper side) in the thickness direction z. The obverse surface 101 is covered with the sealing resin 50. The first chip 21 is mounted on the obverse surface 101 of the first mount portion 10A. The reverse surface 102 of the first mount portion 10A faces the side opposite to the side where the first chip 21 is located in the thickness direction z. The second chip 22 is mounted on the obverse surface 101 of the second mount portion 10B. The reverse surface 102 of the second mount portion 10B faces the side opposite to the side where the second chip 22 is located in the thickness direction z. The reverse surface 102 is exposed from the sealing resin 50. The reverse surface 102 may be plated with tin (Sn).

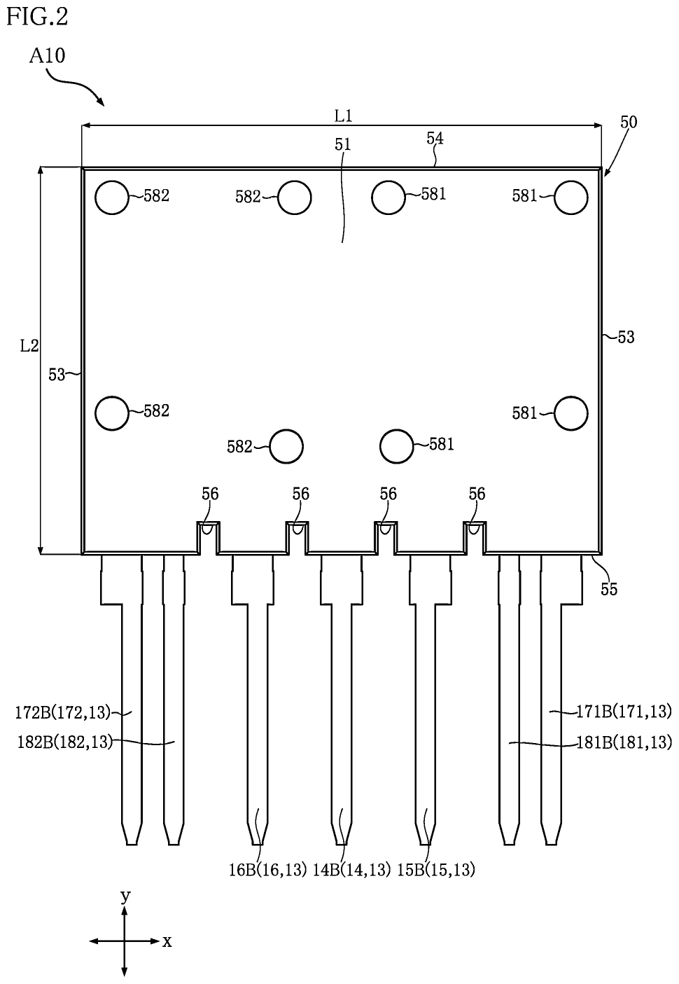

As shown in FIGS. 3, 5, and 9 to 11, the sealing resin 50 covers the semiconductor circuit section 20 (the first chip 21 and the second chip 22), the two conductive members 31 and 32, and at least a portion of each of the first mount portion 10A and the second mount portion 10B. The sealing resin 50 further covers a portion of each of the terminal leads 13, and the conductive members 41A, 41B, 42A, and 42B. The sealing resin 50 has electrical insulation properties. The sealing resin 50 includes, for example, a black epoxy resin. As shown in FIG. 2, the dimension L1 in the first direction x of the sealing resin 50 is longer than the dimension L2 in the second direction y of the sealing resin 50. The sealing resin 50 has a resin obverse surface 51, a resin reverse surface 52, a pair of first side surfaces 53, a second side surface 54, a third side surface 55, a plurality of recesses 56, a groove 57, and a plurality of recesses 581 and 582.

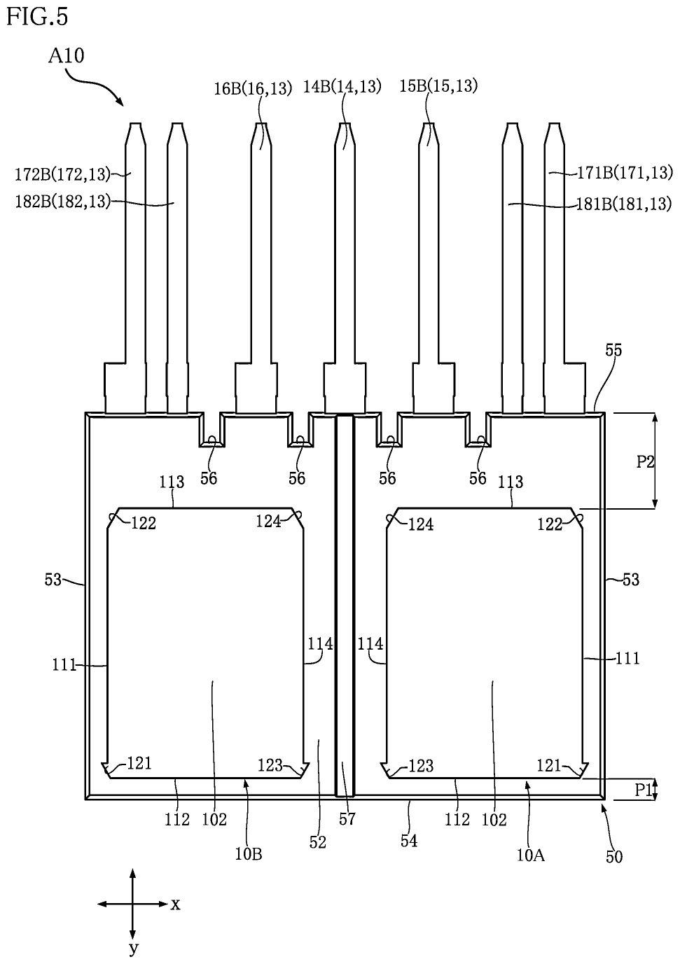

As shown in FIG. 9, the resin obverse surface 51 faces the same side as the obverse surfaces 101 of the first mount portion 10A and the second mount portion 10B in the thickness direction z. As shown in FIG. 9, the resin reverse surface 52 faces away from the resin obverse surface 51 in the thickness direction z. As shown in FIG. 5, the reverse surfaces 102 of the first mount portion 10A and the second mount portion 10B are exposed from the resin reverse surface 52.

As shown in FIGS. 2, 5, and 6, the pair of first side surfaces 53 are spaced apart from each other in the first direction x. The first side surfaces 53 face in the first direction x and extend in the second direction y. The first side surfaces 53 are connected to the resin obverse surface 51 and the resin reverse surface 52.

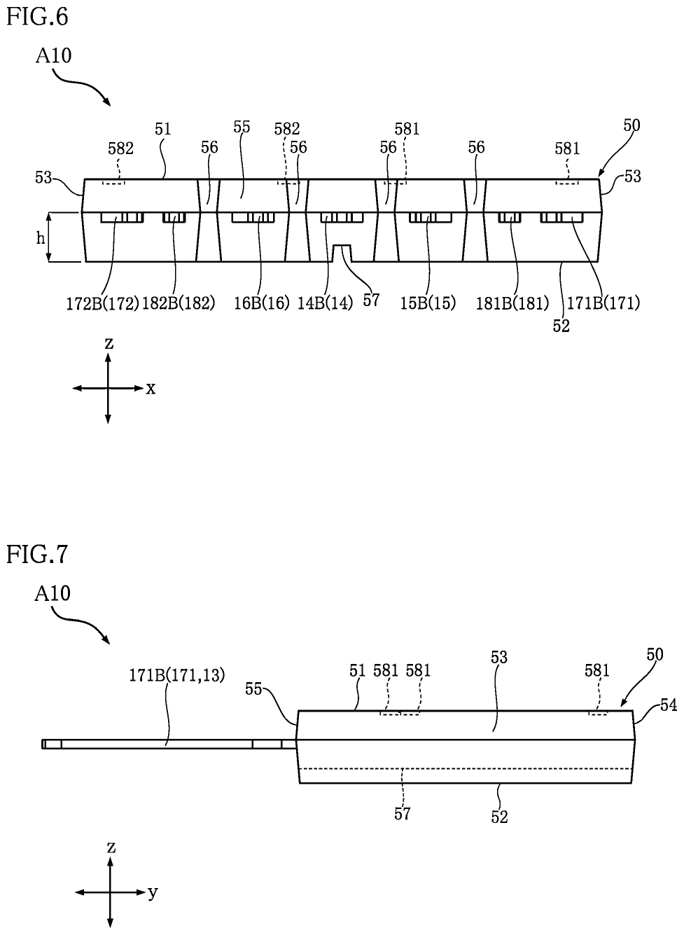

As shown in FIGS. 2, 5, and 7, the second side surface 54 and the third side surface 55 are spaced apart from each other in the second direction y. The second side surface 54 and the third side surface 55 face away from each other in the second direction y and extend in the first direction x. The second side surface 54 and the third side surface 55 are connected to the resin obverse surface 51 and the resin reverse surface 52. As shown in FIG. 6, the plurality of terminal leads 13 are exposed from the third side surface 55.

As shown in FIGS. 2, 5, and 6, the plurality of recesses 56 are recessed from the third side surface 55 in the second direction y and extend from the resin obverse surface 51 to the resin reverse surface 52 in the thickness direction z. In the first direction x, the plurality of recesses 56 are individually located between the seventh terminal lead 182 and the third terminal lead 16, between the third terminal lead 16 and the first terminal lead 14, between the first terminal lead 14 and the second terminal lead 15, and between the second terminal lead 15 and the fifth terminal lead 181.

As shown in FIGS. 5, 6, and 9, the groove 57 is recessed from the resin reverse surface 52 in the thickness direction z and extends along the second direction y. The opposite ends of the groove 57 in the second direction y are connected to the second side surface 54 and the third side surface 55, respectively. As viewed in the thickness direction z, the groove 57 divides the reverse surface 102 of the first mount portion 10A and the reverse surface 102 of the second mount portion 10B.

As shown in FIGS. 1, 6, 7, and 9, each of the plurality of recesses 581 and 582 is recessed from the resin obverse surface 51 in the thickness direction z. The shape in plan view of each of the recesses 581 and 582 is not particularly limited, but is circular in the illustrated example. The recesses 581 overlap with the first mount portion 10A in plan view. In the illustrated example, the recesses 581 are individually located near the four corners of the first mount portion 10A in plan view. The recesses 582 overlap with the second mount portion 10B in plan view. In the illustrated example, the recesses 582 are individually located near the four corners of the second mount portion 10B in plan view. The recesses 581 are formed by pins used to fix the first mount portion 10A during the manufacture of the semiconductor device A10. Before the sealing resin 50 is formed, the pins are pressed against the first mount portion 10A to fix the first mount portion 10A. In this state, the formation of the sealing resin 50 is started. The pins are pulled out before the formation of the sealing resin 50 is completed. Thus, the sealing resin 50 is formed in at least portions of the regions where the pins have been placed, so that the obverse surface 101 of the first mount portion 10A is covered with the sealing resin 50. The recesses 581 are the traces formed during the molding process of the sealing resin 50. Likewise, the recesses 582 are formed by pins used to fix the second mount portion 10B during the manufacture of the semiconductor device A10. The recesses 582 are the traces formed during the molding process of the sealing resin 50.

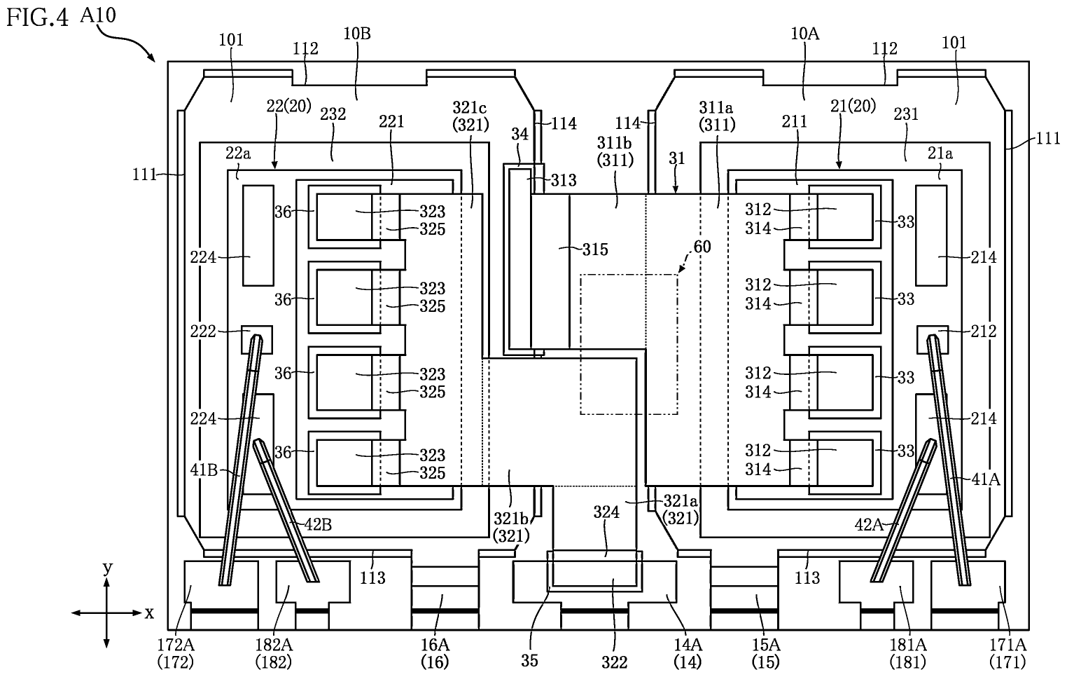

As shown in FIGS. 4 and 5, each of the first mount portion 10A and the second mount portion 10B has a first end surface 111, a second end surface 112, a third end surface 113, and a fourth end surface 114. The first end surface 111, the second end surface 112, the third end surface 113, and the fourth end surface 114 are covered with the sealing resin 50. The first end surface faces in the first direction x and extends in the second direction y. The first end surface 111 is located closest to one of the pair of first side surfaces 53 of the sealing resin 50. The second end surface 112 faces in the second direction y and extends in the first direction x. The second end surface 112 is located closest to the second side surface 54 of the sealing resin 50. The third end surface 113 faces away from the second end surface 112 in the second direction y and extends in the first direction x. The third end surface 113 is located closest to the third side surface 55 of the sealing resin 50. The fourth end surface 114 faces away from the first end surface 111 in the first direction x and extends in the second direction y. As shown in FIG. 9, the groove 57 is located between the fourth end surface 114 of the first mount portion 10A and the fourth end surface 114 of the second mount portion 10B.

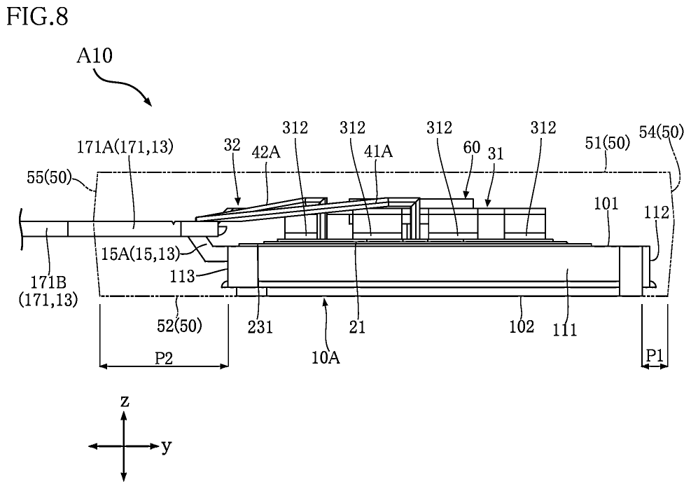

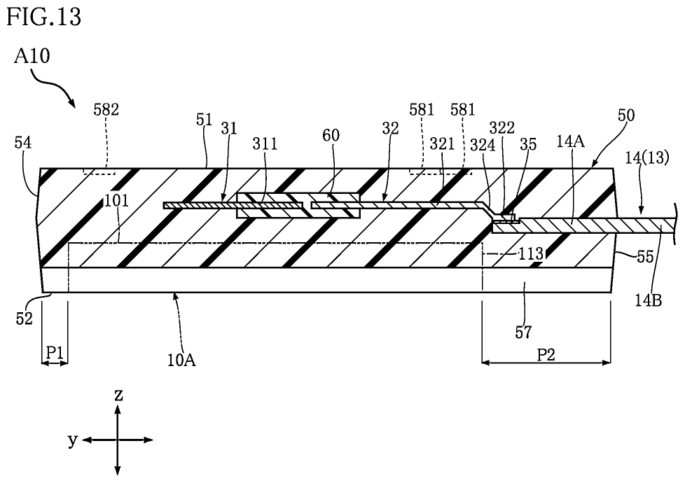

As shown in FIGS. 8 and 13, the distance P2 between the third end surface 113 and the third side surface 55 is longer than the distance P1 between the second end surface 112 and the second side surface 54.

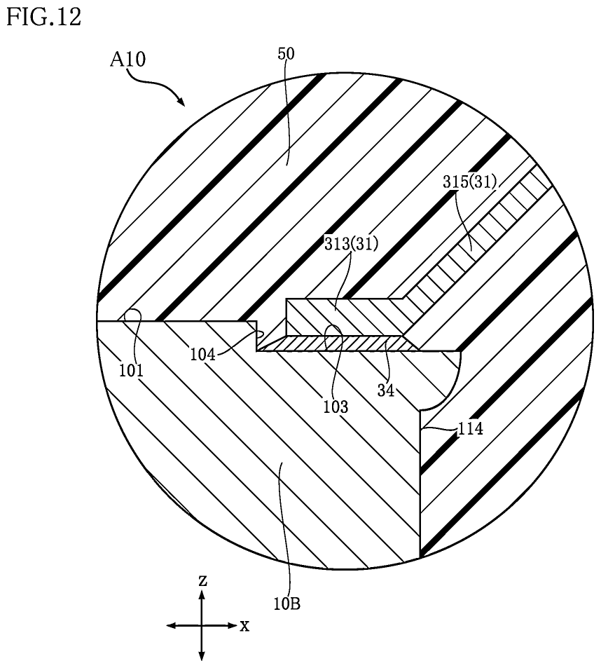

As shown in FIG. 12, the second mount portion 10B has a first seating surface 103 and a first standing surface 104. The first seating surface 103 faces the same side as the obverse surface 101 in the thickness direction z and is located between the obverse surface 101 and the reverse surface 102 in the thickness direction z. The first seating surface 103 is connected to the fourth end surface 114. The first standing surface 104 faces in a direction orthogonal to the thickness direction z and is connected to the first seating surface 103 and the obverse surface 101. The first seating surface 103 and the first standing surface 104 form a step on the second mount portion 10B.

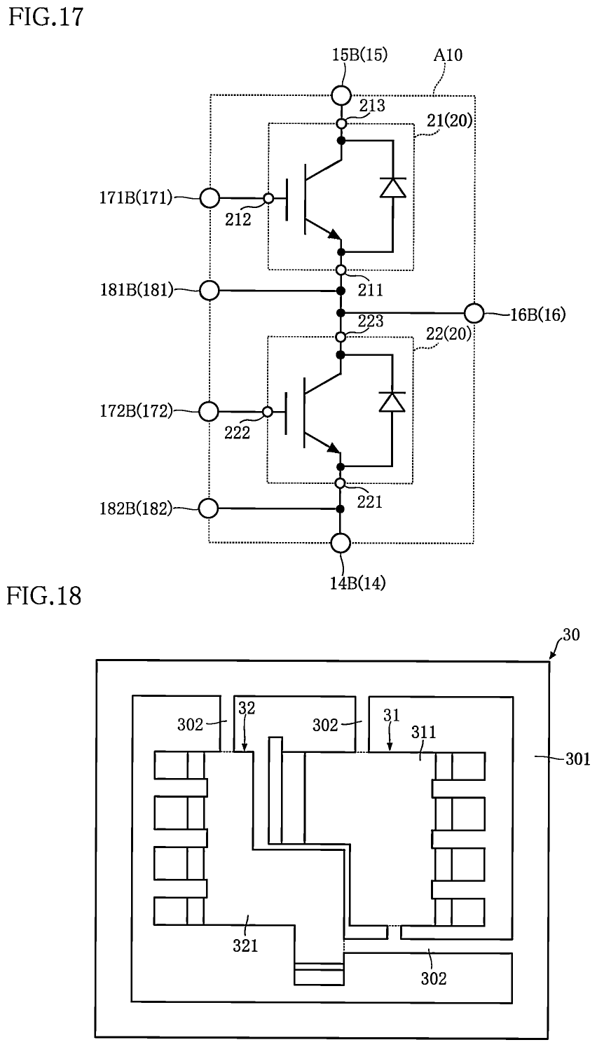

Each of the first chip 21 and the second chip 22 is, for example, a transistor. The transistor is, for example, one of a MOSFET (Metal-Oxide-Semiconductor Field-Effect Transistor), a bipolar transistor, and an IGBT (Insulated Gate Bipolar Transistor). In the present embodiment, each of the first chip 21 and the second chip 22 is an RC-IGBT with a built-in reverse conducting diode, as shown in FIG. 17. The first chip 21 and the second chip 22 may be IGBTs without built-in reverse conducting diodes. Each of the first chip 21 and the second chip 22 includes a compound semiconductor substrate. The composition of the compound semiconductor substrate includes silicon (Si) or silicon carbide (SiC).

As shown in FIGS. 3, 4, 9, and 10, the first chip 21 is mounted on the first mount portion 10A. Preferably, the center of gravity of the first chip 21 overlaps with the center portion of the first mount portion 10A in plan view. The center portion of the first mount portion 10A refers to the region that is located in the center when the first mount portion 10A is divided into Nx parts (where Nx is a positive odd number) in the first direction x and also located in the center when the first mount portion 10A is divided into Ny parts (where Ny is a positive odd number) in the second direction y. Each of Nx and Ny is not limited in any way, but may be 3 or 5, for example.

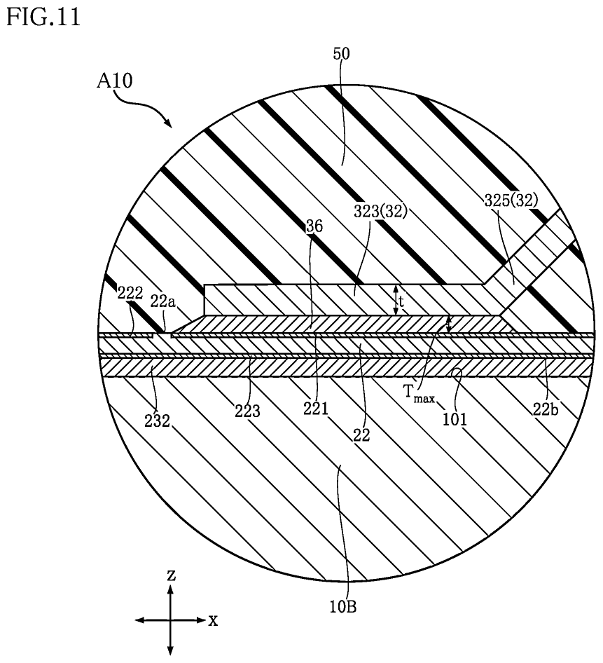

As shown in FIG. 10, the first chip 21 has a first obverse surface 21a and a first reverse surface 21b. The first obverse surface 21a and the first reverse surface 21b are spaced apart from each other in the thickness direction z. The first obverse surface 21a faces in the same direction as the obverse surface 101 of the first mount portion 10A. The first reverse surface 21b faces away from the first obverse surface 21a in the thickness direction z and faces the obverse surface 101 of the first mount portion 10A.

As shown in FIGS. 4 and 10, the first chip 21 has a first obverse surface electrode 211, a plurality of obverse surface electrodes 212 and 214, and a first reverse surface electrode 213.

The first obverse surface electrode 211 is disposed on the first obverse surface 21a. The current corresponding to the power after being converted by the first chip 21 flows in the first obverse surface electrode 211. The first obverse surface electrode 211 is, for example, an emitter electrode in the case where the first chip 21 is an IGBT, and is, for example, a source electrode in the case where the first chip 21 is a MOSFET. The first obverse surface electrode 211 includes a plurality of metal plating layers. The first obverse surface electrode 211 includes a nickel (Ni) plating layer, and a gold (Au) plating layer laminated on the nickel plating layer. Alternatively, the first obverse surface electrode 211 may include a nickel plating layer, a palladium (Pd) plating layer laminated on the nickel plating layer, and a gold plating layer laminated on the palladium plating layer.

The obverse surface electrode 212 is disposed on the first obverse surface 21a. A first drive signal (gate voltage) for driving the first chip 21 is applied to the obverse surface electrode 212. The obverse surface electrode 212 is, for example, a gate electrode in both cases where the first chip 21 is an IGBT or a MOSFET. In plan view, the area of the obverse surface electrode 212 is smaller than the area of the first obverse surface electrode 211.

The pair of the obverse surface electrodes 214 are disposed on the first obverse surface 21a. Each of the pair of obverse surface electrodes 214 is at the same potential as the first obverse surface electrode 211. Each obverse surface electrode 214 is, for example, an emitter sense electrode in the case where the first chip 21 is an IGBT, and is, for example, a source sense electrode in the case where the first chip 21 is a MOSFET. The obverse surface electrodes 214 are disposed on both sides of the obverse surface electrode 212 in the second direction y in plan view. The first chip 21 may have only one of the pair of obverse surface electrodes 214, or may not have either of the pair of obverse surface electrodes 214.

The first reverse surface electrode 213 is disposed on the first reverse surface 21b. The first reverse surface electrode 213 faces the obverse surface 101 of the first mount portion 10A. The current corresponding to the power before being converted by the first chip 21 flows in the first reverse surface electrode 213. The first reverse surface electrode 213 is, for example, a collector electrode in the case where the first chip 21 is an IGBT, and is, for example, a drain electrode in the case where the first chip 21 is a MOSFET.

As shown in FIGS. 3, 4, 9, and 11, the second chip 22 is mounted on the obverse surface 101 of the second mount portion 10B. Preferably, the center of gravity of the second chip 22 overlaps with the center portion of the second mount portion 10B in plan view. The center portion of the second mount portion 10B refers to the region that is located in the center when the second mount portion 10B is divided into Nx parts (where Nx is a positive odd number) in the first direction x and also located in the center when the second mount portion 10B is divided into Ny parts (where Ny is a positive odd number) in the second direction y. Each of Nx and Ny is not limited in any way, but may be 3 or 5, for example.

As shown in FIG. 11, the second chip 22 has a second obverse surface 22a and a second reverse surface 22b. The second obverse surface 22a and the second reverse surface 22b are spaced apart from each other in the thickness direction z. The second obverse surface 22a faces in the same direction as the obverse surface 101 of the second mount portion 10B. The second reverse surface 22b faces away from the second obverse surface 22a in the thickness direction z and faces the obverse surface 101 of the second mount portion 10B.

As shown in FIGS. 4 and 11, the second chip 22 has a second obverse surface electrode 221, a plurality of obverse surface electrodes 222 and 224, and a second reverse surface electrode 223.

The second obverse surface electrode 221 is disposed on the second obverse surface 22a. The current corresponding to the power after being converted by the second chip 22 flows in the second obverse surface electrode 221. The second obverse surface electrode 221 is, for example, an emitter electrode in the case where the second chip 22 is an IGBT, and is, for example, a source electrode in the case where the second chip 22 is a MOSFET. As with the first obverse surface electrode 211, the second obverse surface electrode 221 includes a plurality of metal plating layers. The second obverse surface electrode 221 includes a nickel (Ni) plating layer, and a gold (Au) plating layer laminated on the nickel plating layer. Alternatively, the second obverse surface electrode 221 may include a nickel plating layer, a palladium (Pd) plating layer laminated on the nickel plating layer, and a gold plating layer laminated on the palladium plating layer.

The obverse surface electrode 222 is disposed on the second obverse surface 22a. A second drive signal (gate voltage) for driving the second chip 22 is applied to the obverse surface electrode 222. The obverse surface electrode 212 is, for example, a gate electrode in both cases where the second chip 22 is an IGBT or a MOSFET. In plan view, the area of the obverse surface electrode 222 is smaller than the area of the second obverse surface electrode 221.

The pair of the obverse surface electrodes 224 are disposed on the second obverse surface 22a. Each of the pair of obverse surface electrodes 224 is at the same potential as the second obverse surface electrode 221. Each obverse surface electrode 224 is, for example, an emitter sense electrode in the case where the second chip 22 is an IGBT, and is, for example, a source sense electrode in the case where the second chip 22 is a MOSFET. The pair of obverse surface electrodes 224 are disposed on both sides in the second direction y of the obverse surface electrode 222 in plan view. The second chip 22 may have only one of the pair of obverse surface electrodes 224, or may not have either of the pair of obverse surface electrodes 224.

The second reverse surface electrode 223 is disposed on the second reverse surface 22b. The second reverse surface electrode 223 faces the obverse surface 101 of the second mount portion 10B. The current corresponding to the power before being converted by the second chip 22 flows in the second reverse surface electrode 223. The second reverse surface electrode 223 is, for example, a collector electrode in the case where the second chip 22 is an IGBT, and is, for example, a drain electrode in the case where the second chip 22 is a MOSFET.

The semiconductor device A10 further includes two die bonding layers 231 and 232. The two die bonding layers 231 and 232 are electrically conductive. The die bonding layers 231 and 232 are, for example, solder. Alternatively, the die bonding layers 231 and 232 may be a sintered metal.

As shown in FIGS. 9 and 10, the die bonding layer 231 is interposed between the obverse surface 101 of the first mount portion 10A and the first reverse surface electrode 213 of the first chip 21. The die bonding layer 231 bonds the obverse surface 101 of the first mount portion 10A and the first reverse surface electrode 213 of the first chip 21. Thus, the first reverse surface electrode 213 of the first chip 21 electrically conducts to the first mount portion 10A.

As shown in FIGS. 9 and 11, the die bonding layer 232 is interposed between the obverse surface 101 of the second mount portion 10B and the second reverse surface electrode 223 of the second chip 22. The die bonding layer 232 bonds the obverse surface 101 of the second mount portion 10B and the second reverse surface electrode 223 of the second chip 22. Thus, the second reverse surface electrode 223 of the second chip 22 electrically conducts to the second mount portion 10B.

As understood from FIG. 3 and FIG. 4, the plurality of terminal leads 13 are located on the side opposite to the side which the second end surfaces 112 face in the second direction y with respect to the first mount portion 10A and the second mount portion 10B. At least one of the plurality of terminal leads 13 electrically conducts to either the first chip 21 or the second chip 22. The plurality of terminal leads 13 are arranged along the first direction x. The plurality of terminal leads 13 include a first terminal lead 14, a second terminal lead 15, a third terminal lead 16, a fourth terminal lead 171, a fifth terminal lead 181, a sixth terminal lead 172, and a seventh terminal lead 182.

As shown in FIG. 3, the first terminal lead 14 is spaced apart from the first mount portion 10A and the second mount portion 10B in the second direction y and located between the second terminal lead 15 and the third terminal lead 16 in the first direction x. The first terminal lead 14 extends along the second direction y. The first terminal lead 14 electrically conducts to the second obverse surface electrode 221 of the second chip 22. The first terminal lead 14 includes a covered portion 14A and an exposed portion 14B. As shown in FIG. 3, the covered portion 14A is covered with the sealing resin 50. As shown in FIGS. 3, 5, and 6, the exposed portion 14B is connected to the covered portion 14A and exposed from the third side surface 55 of the sealing resin 50. The exposed portion 14B extends away from the first mount portion 10A and the second mount portion 10B in the second direction y. The surface of the exposed portion 14B may be plated with tin.

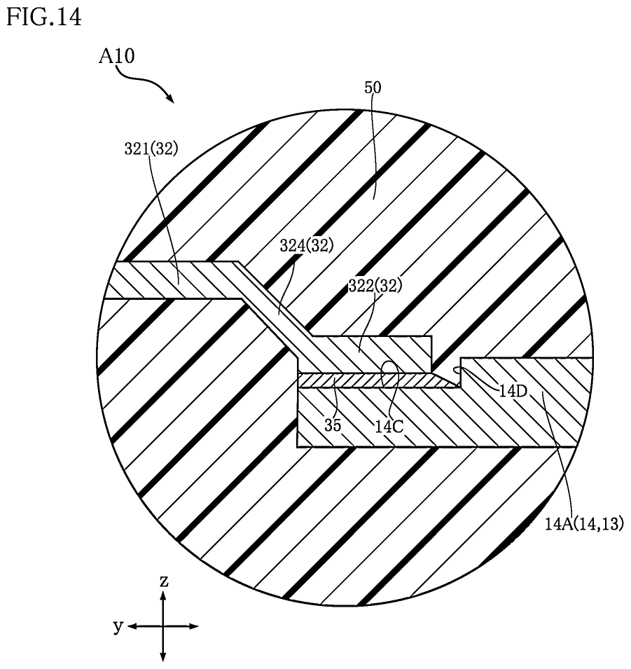

As shown in FIG. 14, the covered portion 14A of the first terminal lead 14 has a second seating surface 14C and a second standing surface 14D. The second seating surface 14C faces the same side as the obverse surfaces 101 of the first mount portion 10A and the second mount portion 10B in the thickness direction z and is located on the lower side in the thickness direction z from the upper surface (the surface facing the upper side in the thickness direction z) of the covered portion 14A. The second standing surface 14D faces in a direction orthogonal to the thickness direction z and is connected to the second seating surface 14C and the upper surface of the covered portion 14A. The second seating surface 14C and the second standing surface 14D form a step on the covered portion 14A of the first terminal lead 14.

As shown in FIG. 3, the second terminal lead 15 includes a portion extending along the second direction y and is connected to the first mount portion 10A. Thus, the second terminal lead 15 electrically conducts to the first reverse surface electrode 213 of the first chip 21 via the first mount portion 10A. The second terminal lead 15 is the P terminal (positive electrode) to which the DC power supply voltage to be converted is applied. The second terminal lead 15 includes a covered portion 15A and an exposed portion 15B. As shown in FIG. 4, the covered portion 15A is connected to the third end surface 113 of the first mount portion 10A and covered with the sealing resin 50. The covered portion 15A is bent as viewed in the first direction x. As shown in FIGS. 3, 5, and 6, the exposed portion 15B is connected to the covered portion 15A and exposed from the third side surface 55 of the sealing resin 50. The exposed portion 15B extends away from the first mount portion 10A in the second direction y. The surface of the exposed portion 15B may be plated with tin.

As shown in FIG. 3, the third terminal lead 16 includes a portion extending along the second direction y and is connected to the second mount portion 10B. Thus, the third terminal lead 16 electrically conducts to the second reverse surface electrode 223 of the second chip 22 via the second mount portion 10B. The AC power after being converted by the first chip 21 and the second chip 22 is outputted from the third terminal lead 16. The third terminal lead 16 includes a covered portion 16A and an exposed portion 16B. As shown in FIG. 4, the covered portion 16A is connected to the third end surface 113 of the second mount portion 10B and covered with the sealing resin 50. The covered portion 16A is bent as viewed in the first direction x, as with the covered portion 15A of the second terminal lead 15. As shown in FIGS. 3, 5, and 6, the exposed portion 16B is connected to the covered portion 16A and exposed from the third side surface 55 of the sealing resin 50. The exposed portion 16B extends away from the second mount portion 10B in the second direction y. The surface of the exposed portion 16B may be plated with tin.

As shown in FIG. 3, the fourth terminal lead 171 is spaced apart from the first mount portion 10A in the second direction y and located on one side in the first direction x. As shown in FIG. 3, the sixth terminal lead 172 is spaced apart from the second mount portion 10B in the second direction y and located on the other side in the first direction x. The fourth terminal lead 171 electrically conducts to the obverse surface electrode 212 (the gate electrode) of the first chip 21. A drive signal (gate voltage) for driving the first chip 21 is applied to the fourth terminal lead 171. The sixth terminal lead 172 electrically conducts to the obverse surface electrode 222 (the gate electrode) of the second chip 22. A drive signal (gate voltage) for driving the second chip 22 is applied to the sixth terminal lead 172.

As shown in FIG. 3, the fourth terminal lead 171 includes a covered portion 171A and an exposed portion 171B. The covered portion 171A is covered with the sealing resin 50. As shown in FIGS. 3, 5, and 6, the exposed portion 171B is connected to the covered portion 171A and exposed from the third side surface 55 of the sealing resin 50. The exposed portion 171B extends away from the first mount portion 10A in the second direction y. The surface of the exposed portion 17B may be plated with tin.

As shown in FIG. 3, the sixth terminal lead 172 includes a covered portion 172A and an exposed portion 172B. The covered portion 172A is covered with the sealing resin 50. As shown in FIGS. 3, 5, and 6, the exposed portion 172B is connected to the covered portion 172A and exposed from the sealing resin 50. The exposed portion 172B extends away from the second mount portion 10B in the second direction y. The surface of the exposed portion 17B may be plated with tin.

As shown in FIG. 3, the fifth terminal lead 181 is spaced apart from the first mount portion 10A in the second direction y and located between the second terminal lead 15 and the fourth terminal lead 171 in the first direction x. As shown in FIG. 3, the seventh terminal lead 182 is spaced apart from the second mount portion 10B in the second direction y and located between the third terminal lead 16 and the sixth terminal lead 172 in the first direction x. The fifth terminal lead 181 electrically conducts to the obverse surface electrode 214 (the emitter sense electrode) of the first chip 21. A voltage corresponding to the current flowing in the obverse surface electrode 214 (the first obverse surface electrode 211) of the first chip 21 is applied to the fifth terminal lead 181. The seventh terminal lead 182 electrically conducts to the second obverse surface electrode 221 (the emitter sense electrode) of the second chip 22. A voltage corresponding to the current flowing in the obverse surface electrode 224 (the second obverse surface electrode 221) of the second chip 22 is applied to the seventh terminal lead 182.

As shown in FIG. 3, the fifth terminal lead 181 includes a covered portion 181A and an exposed portion 181B. The covered portion 181A is covered with the sealing resin 50. As shown in FIGS. 3, 5, and 6, the exposed portion 181B is connected to the covered portion 181A and exposed from the third side surface 55 of the sealing resin 50. The exposed portion 181B extends away from the first mount portion 10A in the second direction y. The surface of the exposed portion 18B may be plated with tin.

As shown in FIG. 3, the seventh terminal lead 182 includes a covered portion 182A and an exposed portion 182B. The covered portion 182A is covered with the sealing resin 50. As shown in FIGS. 3, 5, and 6, the exposed portion 182B is connected to the covered portion 182A and exposed from the third side surface 55 of the sealing resin 50. The exposed portion 182B extends away from the second mount portion 10B in the second direction y. The surface of the exposed portion 18B may be plated with tin.

As shown in FIG. 6, in the semiconductor device A10, the heights h of the exposed portion 14B of the first terminal lead 14, the exposed portion 15B of the second terminal lead 15, and the exposed portion 16B of the third terminal lead 16 are the same (or approximately the same). Furthermore, the thicknesses of these portions are the same (or approximately the same). Thus, as viewed in the first direction x, at least a portion (the exposed portion 14B) of the first terminal lead 14 overlaps with each of the second terminal lead 15 and the third terminal lead 16 (see FIG. 7).

The conductive member 31 electrically conducts to the semiconductor circuit section 20 (the first chip 21). The conductive member 31 is an example of the “first conductive member” in the claims. As shown in FIG. 3, the conductive member 31 is bonded to the first obverse surface electrode 211 of the first chip 21 and the second mount portion 10B. Thus, the first obverse surface electrode 211 electrically conducts to the second mount portion 10B and the second reverse surface electrode 223 of the second chip 22. The composition of the conductive member 31 includes copper. In the semiconductor device A10, the conductive member 31 is a metal clip. The conductive member 31 includes a first main body 311, a plurality of first bond portions 312, a second bond portion 313, a plurality of first connecting portions 314, and a second connecting portion 315.

As shown in FIGS. 3 and 4, the first main body 311 forms a main portion of the conductive member 31. The first main body 311 extends in the first direction x. In the illustrated example, the first main body 311 extends in a straight line between the first chip 21 and the second chip 22 in plan view. As shown in FIG. 8, the first main body 311 extends across the gap between the first mount portion 10A and the second mount portion 10B. The first main body 311 is located on the upper side in the thickness direction z from the first bond portions 312 and the second bond portion 313. As shown in FIG. 4, the first main body 311 includes two sections 311a and 311b.

As shown in FIG. 4, the section 311a is connected to the plurality of first connecting portions 314 and the section 311b. The edge of the section 311a that is connected to the first connecting portions 314 is branched into a plurality of parts. The section 311b is connected to the section 311a and the second connecting portion 315. The width (the dimension in the second direction y) of the section 311b is smaller than the width (the dimension in the second direction y) of the section 311a. The first main body 311 having such a configuration has an L-shape in plan view as shown in FIG. 4.

As shown in FIGS. 3, 4, 11, and 15, each of the first bond portions 312 is bonded to the first obverse surface electrode 211 of the first chip 21. As shown in FIGS. 3, 4, and 15, the first bond portions 312 are spaced apart from each other in the second direction y. The first bond portions 312 are arranged parallel (or generally parallel) to each other in plan view. Each of the first bond portions 312 is connected to the first main body 311 (the section 311a) via one of the first connecting portions 314. The first connecting portions 314 are connected to the first main body 311 and the first bond portions 312. As shown in FIG. 9, each first connecting portion 314 is bent in the thickness direction z.

As shown in FIGS. 3, 9, and 12, the second bond portion 313 is bonded to the first seating surface 103 of the second mount portion 10B. The second bond portion 313 extends in the second direction y. At least a part of the second bond portion 313 is included in a region defined by the first seating surface 103 and the first standing surface 104 of the second mount portion 10B. The second bond portion 313 is connected to the first main body 311 (the section 311b) via the second connecting portion 315. As shown in FIG. 9, the second connecting portion 315 is bent in the thickness direction z. The second bond portion 313 is located opposite to the first bond portions 312 across the first main body 311.

As shown in FIGS. 9 and 11, the semiconductor device A10 further includes first bonding layers 33. Each first bonding layer 33 is interposed between the first obverse surface electrode 211 of the first chip 21 and one of the first bond portions 312. The first bonding layers 33 bond the first obverse surface electrode 211 and the first bond portions 312. The first bonding layers 33 are electrically conductive. The first bonding layers 33 are, for example, solder. Alternatively, the first bonding layers 33 may be a sintered metal.

The thickness t (see FIG. 10) of each of the first bond portions 312 is equal to or greater than 0.1 mm and equal to or less than twice the maximum thickness Tₘₐₓ (see FIG. 10) of the first bonding layers 33. The maximum thickness Tₘₐₓ of the first bonding layers 33 is greater than the thickness of the first chip 21.

As shown in FIGS. 9 and 12, the semiconductor device A10 further includes a second bonding layer 34. The second bonding layer 34 is interposed between the first seating surface 103 of the second mount portion 10B and the second bond portion 313. The second bonding layer 34 bonds the second mount portion 10B and the second bond portion 313. The second bonding layer 34 is electrically conductive. The second bonding layer 34 is, for example, solder. Alternatively, the second bonding layer 34 may be a sintered metal.

The conductive member 32 electrically conducts to the semiconductor circuit section 20 (the second chip 22). The conductive member 32 is an example of the “second conductive member” in the claims. As shown in FIG. 3, the conductive member 32 is bonded to the second obverse surface electrode 221 of the second chip 22 and the covered portion 14A of the first terminal lead 14. Thus, the second obverse surface electrode 221 electrically conducts to the first terminal lead 14. The composition of the conductive member 32 includes copper. In the semiconductor device A10, the conductive member 32 is a metal clip. The conductive member 32 includes a second main body 321, a third bond portion 322, a plurality of fourth bond portions 323, a third connecting portion 324, and a plurality of fourth connecting portions 325.

As shown in FIGS. 3 and 4, the second main body 321 forms a main portion of the conductive member 32. In in plan view, the second main body 321 is bent into a hook shape. In plan view, the second main body 321 overlaps with the obverse surface 101 of the second mount portion 10B. The second main body 321 is located on the upper side in the thickness direction z from the third bond portion 322 and the fourth bond portions 323. As shown in FIG. 4, the second main body 321 includes a plurality of sections 321a, 321b, and 321c.

As shown in FIG. 4, the section 321a is connected to the third connecting portion 324 and the section 321b. In plan view, the section 321a extends from the third connecting portion 324 in the second direction y. The section 321b is connected to two sections 321a and 321c. In plan view, the section 321b extends in the first direction x. In the present embodiment, when the semiconductor device A10 is energized, the current flowing in the section 311b and the current flowing in the section 321b are in opposite directions. The section 321c is connected to the section 321b and the fourth connecting portions 325. The section 321c has a band shape extending in the second direction y in plan view.

As shown in FIGS. 3, 4, 13, and 14, the third bond portion 322 is bonded to the second seating surface 14C of the first terminal lead 14. The third bond portion 322 extends in the first direction x. At least a part of the third bond portion 322 is included in a region defined by the second seating surface 14C and the second standing surface 14D of the first terminal lead 14. The third bond portion 322 is connected to the second main body 321 (the section 321a) via the third connecting portion 324. As shown in FIG. 13, the third connecting portion 324 is bent in the thickness direction z. The third bond portion 322 is located opposite to the fourth bond portions 323 across the second main body 321.

As shown in FIGS. 3, 4, 9, 11, and 16, each of the fourth bond portions 323 is bonded to the second obverse surface electrode 221 of the second chip 22. As shown in FIGS. 3, 4, and 16, the fourth bond portions 323 are spaced apart from each other in the second direction y. The fourth bond portions 323 are arranged parallel (or generally parallel) to each other in plan view. Each of the fourth bond portions 323 is connected to the second main body 321 (the section 321c) via one of the fourth connecting portions 325. The fourth connecting portions 325 are connected to the second main body 321 and the fourth bond portions 323. As shown in FIG. 9, each fourth connecting portion 325 is bent in the thickness direction z.

As shown in FIGS. 9 and 14, the semiconductor device A10 further includes a third bonding layer 35. The third bonding layer 35 is interposed between the second seating surface 14C of the first terminal lead 14 and the third bond portion 322. The third bonding layer 35 bonds the covered portion 14A of the first terminal lead 14 and the third bond portion 322. The third bonding layer 35 is electrically conductive. The third bonding layer 35 is, for example, solder. Alternatively, the third bonding layer 35 may be a sintered metal.

As shown in FIGS. 9, 11, and 16, the semiconductor device A10 further includes fourth bonding layers 36. The fourth bonding layers 36 are interposed between the second obverse surface electrode 221 of the second chip 22 and the fourth bond portions 323. The fourth bonding layers 36 bond the second obverse surface electrode 221 of the second chip 22 and the fourth bond portions 323. The fourth bonding layers 46 are electrically conductive. The fourth bonding layers 46 are, for example, solder. Alternatively, the fourth bonding layers 46 may be a sintered metal.

The thickness t (see FIG. 11) of each of the fourth bond portions 323 is equal to or greater than 0.1 mm and equal to or less than twice the maximum thickness Tₘₐₓ (see FIG. 11) of the fourth bonding layers 36. The maximum thickness Tₘₐₓ of the fourth bonding layers 36 is greater than the thickness of the second chip 22.

The conductive members 41A, 41B, 42A, and 42B are, for example, bonding wires. The composition of each of the conductive members 41A, 41B, 42A, and 42B includes gold. Alternatively, the composition of each of the conductive members 41A, 41B, 42A. and 42B may contain copper or may contain aluminum (Al).

As shown in FIGS. 3 and 4, the conductive member 41A is bonded to the obverse surface electrode 212 of the first chip 21 and the covered portion 171A of the fourth terminal lead 171. Thus, the fourth terminal lead 171 electrically conducts to the obverse surface electrode 212 of the first chip 21. As shown in FIGS. 3 and 4, the conductive member 41B is bonded to the obverse surface electrode 222 of the second chip 22 and the covered portion 172A of the sixth terminal lead 172. Thus, the sixth terminal lead 172 electrically conducts to the obverse surface electrode 222 of the second chip 22.

As shown in FIGS. 3 and 4, the conductive member 42A is bonded to one of the obverse surface electrodes 214 of the first chip 21 and the covered portion 181A of the fifth terminal lead 181. Thus, the fifth terminal lead 181 electrically conducts to the obverse surface electrode 214 of the first chip 21. As shown in FIGS. 3 and 4, the conductive member 42B is bonded to one of the obverse surface electrodes 224 of the second chip 22 and the covered portion 182A of the seventh terminal lead 182. Thus, the seventh terminal lead 182 electrically conducts to the obverse surface electrode 224 of the second chip 22.

As shown in FIGS. 3, 4, and 9, the insulating member 60 is in contact with the two conductive members 31 and 32. The insulating member 60 fixes the two conductive members 31 and 32 to each other. The insulating member 60 is covered with the sealing resin 50. The insulating member 60 contains, for example, the same resin material as the sealing resin 50. The insulating member 60 is not limited in any way as long as it contains an insulating material. The shape in plan view of the insulating member 60 is not limited in any way, and is rectangular in the illustrated example. The insulating member 60 is, for example, formed in the area where the two conductive members 31 and 32 are close to each other in plan view. A portion of the conductive member 31 and a portion of the conductive member 32 are embedded in the insulating member 60 in the thickness direction z. The insulating member 60 is formed, for example, to ride over the first main body 311 of the conductive member 31 and the second main body 321 of the conductive member 32 in plan view. In the present embodiment, the insulating member 60 is not in contact with any of the first connecting portions 314, the second connecting portion 315, the third connecting portion 324, and the fourth connecting portions 325 as shown in FIGS. 3 and 9. The formation area of the insulating member 60 is not limited to the illustrated size and shape as long as it rides over the two conductive members 31 and 32.

In the semiconductor device A10 configured as described above, the first obverse surface electrode 211 of the first chip 21 and the second reverse surface electrode 223 of the second chip 22 are electrically connected as shown in FIG. 17. Thus, the semiconductor device A10 forms a half-bridge circuit with two transistors (the first chip 21 and the second chip 22).

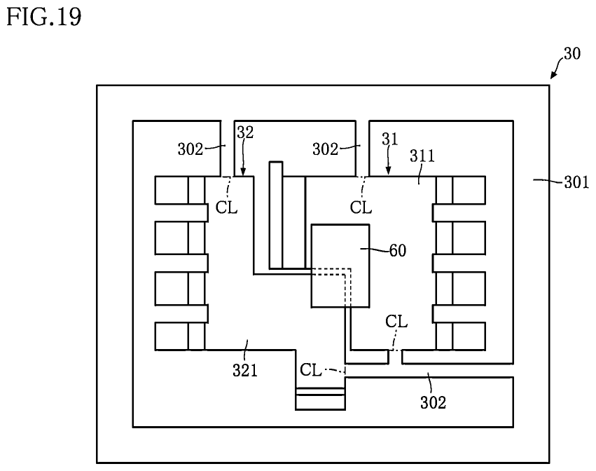

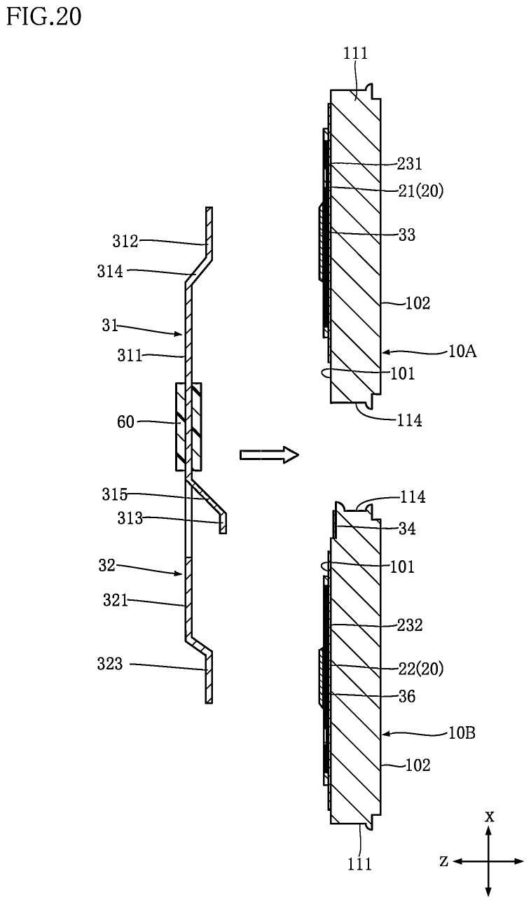

Next, an example of a method for manufacturing the semiconductor device A10 will be described with reference to FIGS. 18 to 20. FIGS. 18 and 19 are plan views each showing a step in the manufacturing method of the semiconductor device A10. FIG. 20 is a sectional view corresponding to FIG. 9, showing a step in the manufacturing method of the semiconductor device A10.

First, a lead frame 30 shown in FIG. 18 is prepared. The lead frame 30 incudes a frame portion 301, a plurality of suspending portions 302, and two conductive members 31 and 32. The two conductive members 31 and 32 are supported on the frame portion 301 via at least some of the suspending portions 302.

Next, as shown in FIG. 19, an insulating member 60 is formed on the lead frame 30. The insulating member 60 is formed to ride over the two conductive members 31 and 32. Thus, in the state of the lead frame 30, the two conductive members 31 and 32 are fixed together by the insulating member 60. The insulating member 60 contains, for example, epoxy resin. In this example, the insulating member 60 is formed by molding, for example.

Next, the two conductive members 31 and 32 are separated from the frame portion 301. For example, cutting along the cutting lines CL shown in FIG. 19 is performed. Thus, the two conductive members 31 and 32 fixed together by the insulating member 60 are obtained.

Next, as shown in FIG. 20, while being fixed together by the insulating member 60, the two conductive members 31 and 32 are bonded to the semiconductor circuit section 20 (the first chip 21 and the second chip 22). Before the step shown in FIG. 20, a lead frame including the first mount portion 10A, the second mount portion 10B, and a plurality of terminal leads 13 is prepared, and the first chip 21 and the second chip 22 are bonded to the first mount portion 10A and the second mount portion 10B, respectively. In the state of the lead frame, the plurality of terminal leads 13 are connected to each other. In the above step of bonding the two conductive members 31 and 32, the conductive member 31 is bonded to the first chip 21 and the second mount portion 10B, and the conductive member 32 is bonded to the second chip 22 and the first terminal lead 14.

Next, after the plurality of conductive members 41A, 41B, 42A, and 42B are formed, the sealing resin 50 covering the parts such as the two conductive members 31 and 32 and the insulating member 60 is formed. Thereafter, the plurality of terminal leads 13 are separated from each other. Through the above steps, the semiconductor device A10 is obtained.

The effects and advantages of the semiconductor device A10 and the manufacturing method according to the first embodiment are as follows.

The semiconductor device A10 includes the insulating member 60 that is in contact with the two conductive members 31 and 32. The two conductive members 31 and 32 are fixed together by the insulating member 60. With such a configuration, during the manufacturing process of the semiconductor device A10, the two conductive members 31 and 32 can be bonded to the semiconductor circuit section 20 (the first chip 21 and the second chip 22) while being fixed together by the insulating member 60. Since the two conductive members 31 and 32 can be collectively disposed in this way, the semiconductor device A10 can improve the production efficiency.

In addition, since the two conductive members 31 and 32 are disposed while being fixed together by the insulating member 60, the semiconductor device A10 can suppress the deviation in the relative positional relationship between the conductive members. Thus, the semiconductor device A10 can prevent the two conductive members 31 and 32 from coming into contact with each other. Moreover, since the deviation in the relative positional relationship can be suppressed, the distance between the two conductive members 31 and 32 can be made small. Thus, the mutual inductance generated by the current flowing in the conductive member 31 and the current flowing in the conductive member 32 can be increased, so that the semiconductor device A10 can reduce the parasitic inductance. Since the distance between the two conductive members 31 and 32 can be made small as mentioned above, the size of each of the two conductive members 31 and 32 can be increased. Therefore, the wiring resistance and the self-inductance of the two conductive members 31 and 32 can be reduced. Thus, the semiconductor device A10 can reduce the parasitic inductance.

In the semiconductor device A10, the first bond portion 312 of the conductive member 31 is bonded to the first obverse surface electrode 211 with the first bonding layer 33. The second bond portion 313 of the conductive member 31 is bonded to the second mount portion 10B with the second bonding layer 34. The third bond portion 322 of the conductive member 32 is bonded to the first terminal lead 14 with the third bonding layer 35. The fourth bond portion 323 of the conductive member 32 is bonded to the second obverse surface electrode 221 with the fourth bonding layer 36. Each of the first bonding layer 33, the second bonding layer 34, the third bonding layer 35, and the fourth bonding layer 36 is, for example, solder. With such a configuration, during the bonding process using the first bonding layer 33, the second bonding layer 34, the third bonding layer 35 and the fourth bonding layer 36, these bonding layers are heated by reflowing. If the two conductive members 31 and 32 are not fixed together by the insulating member 60, the deviation in the relative positional relationship between the two conductive members 31 and 32 becomes more likely to occur. Therefore, in a configuration that requires heating of the first bonding layer 33, the second bonding layer 34, the third bonding layer 35, and the fourth bonding layer 36, fixing the two conductive members 31 and 32 to each other by the insulating member 60 effectively suppresses the deviation in the relative positional relationship between the two conductive members 31 and 32. In other words, the parasitic inductance of the semiconductor device A10 is effectively reduced. By reducing the parasitic inductance of the semiconductor device A10, the generation of surge voltage accompanying the switching operation of the first chip 21 and the second chip 22 can be suppressed.

In the semiconductor device A10, the insulating member 60 is formed in the area where the two conductive members 31 and 32 are close to each other in plan view. By disposing an insulator in the area where the two conductive members 31 and 32 are close to each other, the dielectric strength between the two conductive members 31 and 32 can be ensured.

In the semiconductor device A10, the insulating member 60 contains the same resin material as the sealing resin 50. With such a configuration, the dielectric strength between the two conductive members 31 and 32 can be made generally equal to that in the case where the sealing resin 50 is disposed between the two conductive members 31 and 32. In addition, the difference between the insulating member 60 and the sealing resin 50 in linear expansion coefficient can be suppressed, so the thermal stress caused by the difference in linear expansion coefficient can be suppressed.

In the semiconductor device A10, the insulating member 60 is disposed approximately in the center of the two conductive members 31 and 32 as a whole in plan view, as shown in FIG. 3. In the manufacturing process of the semiconductor device A10, for example, after the cutting along the cutting lines CL shown in FIG. 19, the two conductive members 31 and 32 are transported while being fixed together by the insulating member 60. At this time, the two conductive members 31 and 32 may be transported by suctioning the insulating member 60. In such a case as well, the semiconductor device A10 can prevent the two conductive members 31 and 32 from inclining. In addition, during such transportation by suctioning the insulating member 60, the transporting member does not come into contact with the two conductive members 31 and 32, so that deformation of the two conductive members 31 and 32 is prevented.

In the semiconductor device A10, the semiconductor circuit section 20 includes the first chip 21 and the second chip 22. The first chip 21 and the second chip 22 are covered with the sealing resin 50. In the semiconductor device A10 having such a configuration, the two chips (the first chip 21 and the second chip 22) are sealed together in a single package by the sealing resin 50. Therefore, the mounting area of the semiconductor device A10 on a circuit board can be reduced.

Other embodiments and variation of the semiconductor device according to the present disclosure are described below. The structures of various parts of variations and embodiments may be selectively used in any appropriate combination as long as it is technically compatible.

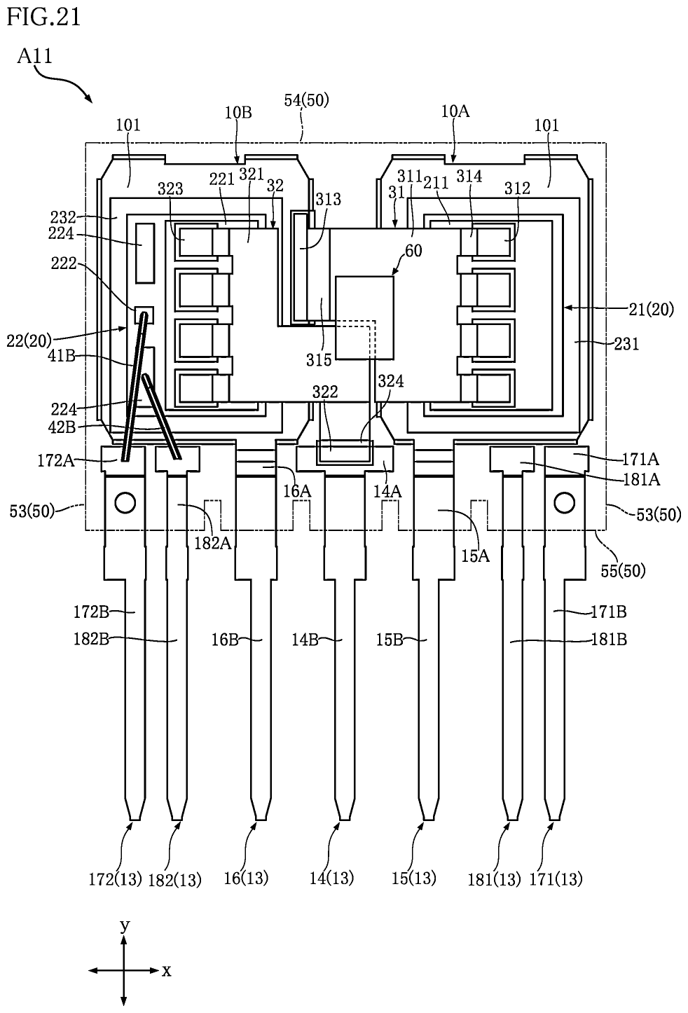

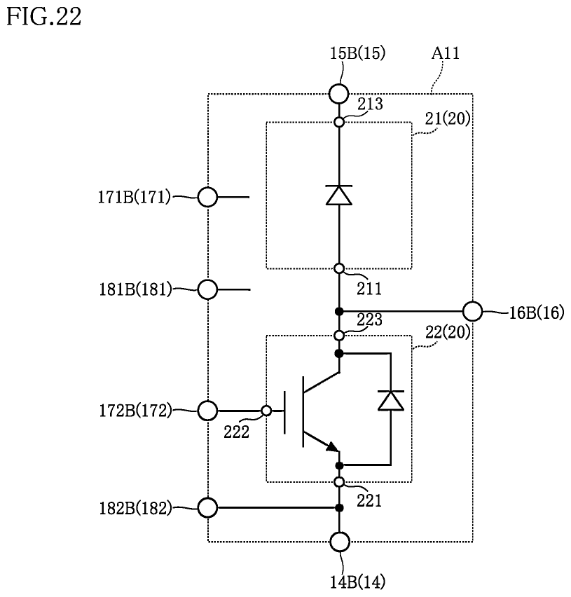

FIGS. 21 and 22 show a semiconductor device A11 according to a first variation of the first embodiment. The semiconductor device A11 differs from the semiconductor device A10 in that the first chip 21 of the semiconductor device All is a diode rather than a transistor.

The first chip 21 of the semiconductor device A11 has a first obverse surface electrode 211 and a first reverse surface electrode 213. As shown in FIG. 21, the first chip 21 of the semiconductor device A11 does not have the obverse surface electrodes 212 and 214. As shown in FIG. 22, the first chip 21 of the semiconductor device All is a diode, the first obverse surface electrode 211 is, for example, an anode electrode, and the first reverse surface electrode 213 is, for example, a cathode electrode.

As shown in FIG. 21, the semiconductor device A11 does not include either of the two conductive members 41A and 42A. With such a configuration, as shown in FIGS. 21 and 22, the fourth terminal lead 171 and the fifth terminal lead 181 do not electrically conduct to either the first chip 21 or the second chip 22. Thus, in the semiconductor device A11, the fourth terminal lead 171 and the fifth terminal lead 181 are non-connected terminals. In the example shown in FIG. 21, the semiconductor device A11 includes the conductive member 42B. Unlike this example, the semiconductor device A11 may no include the conductive member 42B.

In the semiconductor device A11, the first obverse surface electrode 211 (the anode electrode) of the first chip 21 and the second reverse surface electrode 223 (the collector electrode) of the second chip 22 are electrically connected as shown in FIG. 22. In the semiconductor device A11, with respect to the power supply voltage (DC voltage) applied between the first terminal lead 14 and the second terminal lead 15, the high-voltage side serves as a diode, and the low-voltage side serves as a transistor. The semiconductor device A11 is used, for example, as a step-up chopper circuit.

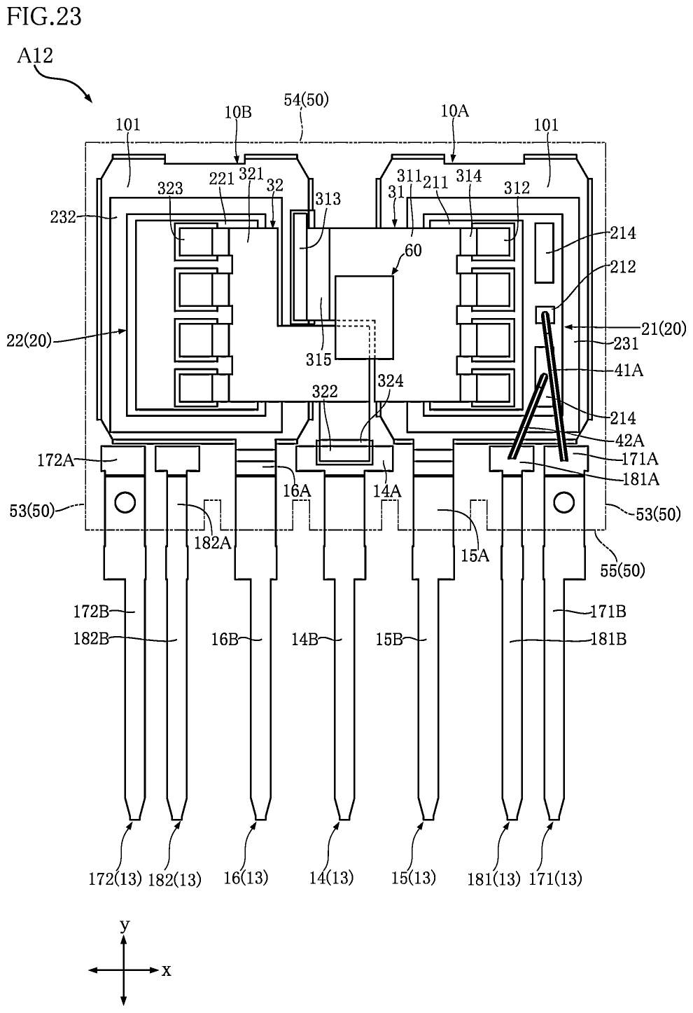

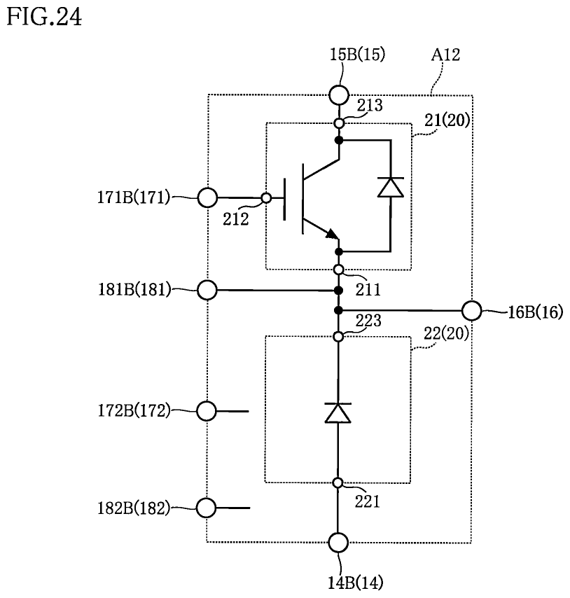

FIGS. 23 and 24 show a semiconductor device A12 according to a second variation of the first embodiment. The semiconductor device A12 differs from the semiconductor device A10 in that the second chip 22 of the semiconductor device A12 is a diode rather than a transistor.

The second chip 22 of the semiconductor device A12 has a second obverse surface electrode 221 and a second reverse surface electrode 223. As shown in FIG. 23, the second chip 22 of the semiconductor device A12 does not have the obverse surface electrodes 222 and 224. As shown in FIG. 24, the second chip 22 of the semiconductor device A12 is a diode, the second obverse surface electrode 221 is, for example, an anode electrode, and the second reverse surface electrode 223 is, for example, a cathode electrode.

As shown in FIG. 23, the semiconductor device A12 does not include either of the two conductive members 41B and 42B. With such a configuration, as shown in FIGS. 23 and 24, the sixth terminal lead 172 and the seventh terminal lead 182 do not electrically conduct to either the first chip 21 or the second chip 22. Thus, in the semiconductor device A12, the sixth terminal lead 172 and the seventh terminal lead 182 are non-connected terminals. In the example shown in FIG. 23, the semiconductor device A12 includes the conductive member 42A. Unlike this example, the semiconductor device A12 may no include the conductive member 42A.

In the semiconductor device A12, the first obverse surface electrode 211 (the emitter electrode) of the first chip 21 and the second reverse surface electrode 223 (the cathode electrode) of the second chip 22 are electrically connected as shown in FIG. 24. In the semiconductor device A12, with respect to the DC voltage applied between the first terminal lead 14 and the second terminal lead 15, the high-voltage side serves as a transistor, and the low-voltage side serves as a diode. The semiconductor device A12 is used, for example, as a step-down chopper circuit.

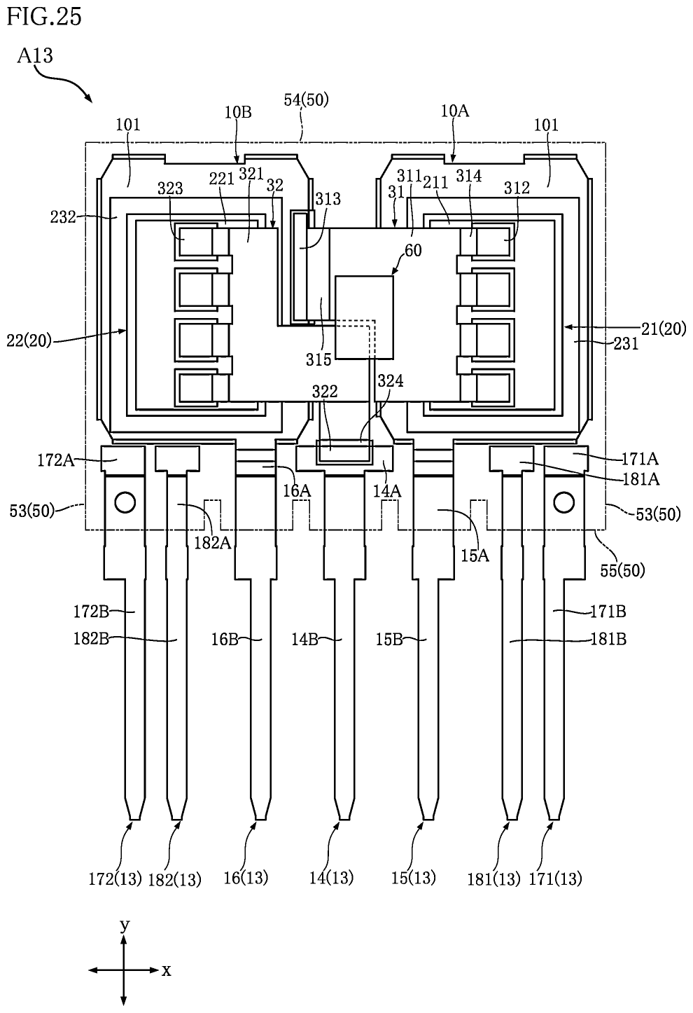

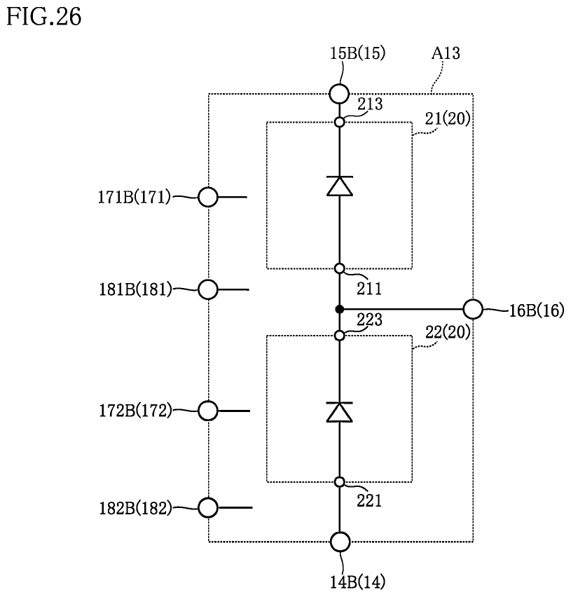

FIGS. 25 and 26 show a semiconductor device A13 according to a third variation of the first embodiment. The semiconductor device A13 differs from the semiconductor device A10 in that each of the first chip 21 and the second chip 22 of the semiconductor device A13 is a diode rather than a transistor.

The first chip 21 of the semiconductor device A13 has a first obverse surface electrode 211 and a first reverse surface electrode 213. As shown in FIG. 25, the first chip 21 of the semiconductor device A13 does not have the obverse surface electrodes 212 and 214. As shown in FIG. 26, the first chip 21 of the semiconductor device A13 is a diode, the first obverse surface electrode 211 is, for example, an anode electrode, and the first reverse surface electrode 213 is, for example, a cathode electrode. The second chip 22 of the semiconductor device A13 has a second obverse surface electrode 221 and a second reverse surface electrode 223. As shown in FIG. 25, the second chip 22 of the semiconductor device A13 does not have the obverse surface electrodes 222 and 224. As shown in FIG. 26, the second chip 22 of the semiconductor device A13 is a diode, the second obverse surface electrode 221 is an anode electrode, and the second reverse surface electrode 223 is a cathode electrode.

As shown in FIG. 25, the semiconductor device A13 does not include any of the conductive members 41A, 42A, 41B, and 42B. With such a configuration, as shown in FIGS. 24 and 25, the fourth terminal lead 171, the fifth terminal lead 181, the sixth terminal lead 172, and the seventh terminal lead 182 do not electrically conduct to either the first chip 21 or the second chip 22. Thus, in the semiconductor device A13, the fourth terminal lead 171, the fifth terminal lead 181, the sixth terminal lead 172, and the seventh terminal lead 182 are non-connected terminals.

In the semiconductor device A13, the first obverse surface electrode 211 (the anode electrode) of the first chip 21 and the second reverse surface electrode 223 (the cathode electrode) of the second chip 22 are electrically connected as shown in FIG. 26. In the semiconductor device A13, with respect to the power supply voltage (DC voltage) applied between the first terminal lead 14 and the second terminal lead 15, both of the high-voltage side and the low-voltage side serve as diodes. The semiconductor device A13 is a diode bridge circuit.

In the semiconductor devices A11 to A13 according to the variations of the first embodiment, as with the semiconductor device A10, the two conductive members 31 and 32 are fixed together by the insulating member 60. Thus, in the semiconductor devices A11 to A13, the two conductive members 31 and 32 can be collectively disposed as with the semiconductor device A10, so that the production efficiency can be improved. The semiconductor devices A11 to A13 have a configuration in common with the semiconductor device A10, thereby achieving the same effect as the semiconductor device A10. For example, the semiconductor devices A11 to A13 can prevent the two conductive members 31 and 32 from coming into contact with each other. Furthermore, the semiconductor devices A11 to A13 can increase the mutual inductance generated by the current flowing in the conductive member 31 and the current flowing in the conductive member 32, and hence, reduce the parasitic inductance.

As understood from the semiconductor devices A10 to A13, the semiconductor device of the present disclosure can form four types of power conversion circuits (a bridge circuit using a transistor, a step-up chopper circuit, a step-down chopper circuit, and a bridge circuit using a diode) by the combinations of the first chip 21 and the second chip 22. On the other hand, the configurations of the parts such as the terminal leads 13 and the sealing resin 50 are common to the semiconductor devices A10 to A13. Therefore, the semiconductor device of the present disclosure can form any of the four types of power conversion circuits while maintaining the same package appearance. In addition, as for the semiconductor device of the present disclosure, the terminal leads 13 and the sealing resin 50 of the same configuration can be employed, regardless of whether each of the first chip 21 and second chip 22 is a transistor or a diode. Therefore, the semiconductor devices of the present disclosure can use a common package structure for any of the above four types of power conversion circuits, which is favorable for improving productivity.

As understood from the semiconductor devices A10 to A13, the semiconductor device of the present disclosure is configured such that the center of gravity of the first chip 21 overlaps with the center portion of the first mount portion 10A in plan view. Such a configuration is favorable for the common parts utilization of the conductive member 31. Likewise, the semiconductor device of the present disclosure is configured such that the center of gravity of the second chip 22 overlaps with the center portion of the second mount portion 10B in plan view. Such a configuration is favorable for the common parts utilization of the conductive member 32.

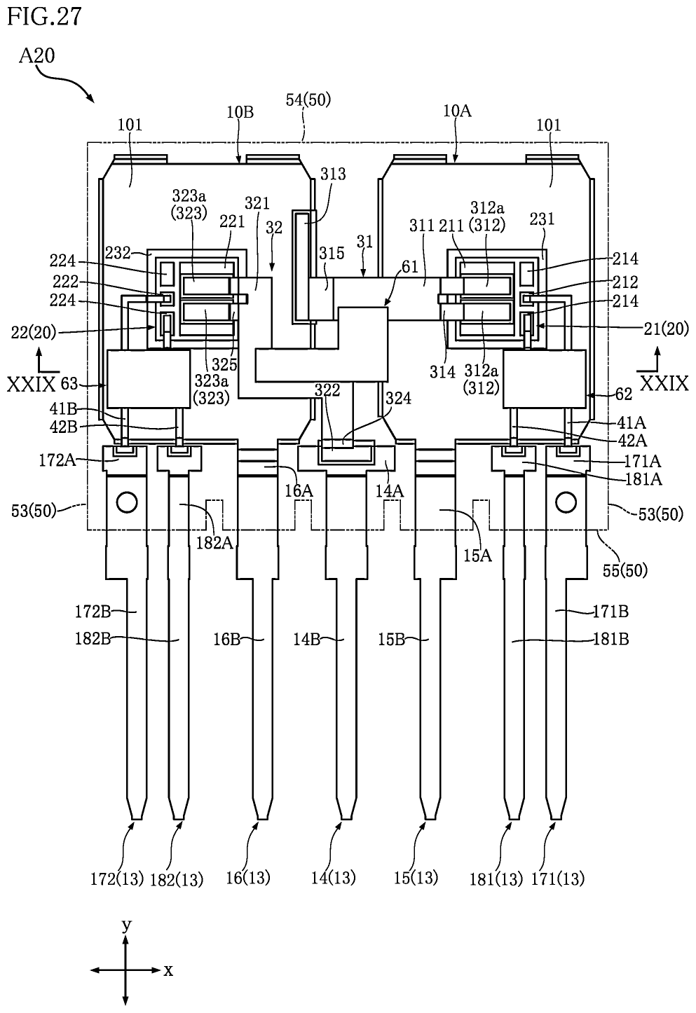

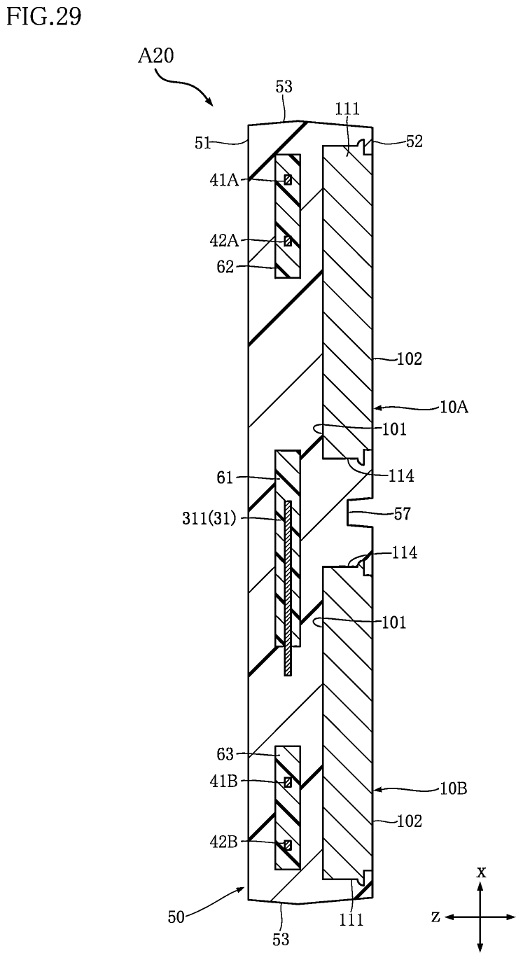

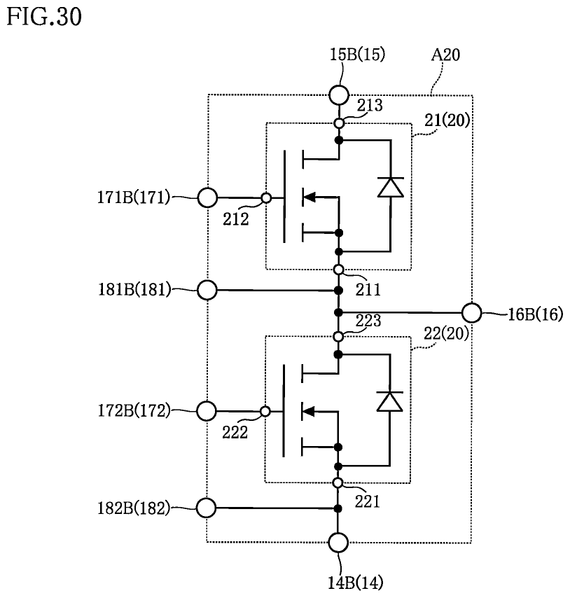

FIGS. 27 to 30 show a semiconductor device A20 according to a second embodiment. The semiconductor device A20 differs from the semiconductor device A10 in the following points. First, each of the conductive members 41A, 42A, 41B, and 42B is a conductive plate member rather than a bonding wire. Second, the semiconductor device of the second embodiment includes a first insulating member 61, a second insulating member 62, and a third insulating member 63, instead of the insulating member 60. In the semiconductor device A20, the first chip 21 and the second chip 22 are, for example, MOSFETs as shown in FIG. 30. However, as with the semiconductor device A10, the first chip and the second chip may be IGBTs (or RC-IGBTs).

The composition of each of the conductive members 41A, 42A, 41B, and 42B includes copper or a copper alloy. Unlike this example, the composition of each of the conductive members 41A, 42A, 41B, and 42B may include other metal materials. The conductive member 41A is bonded to the obverse surface electrode 212 (the first chip 21) and the covered portion 171A (the fourth terminal lead 171) with a conductive bonding material. The conductive member 42A is bonded to the obverse surface electrode 214 (the first chip 21) and the covered portion 181A (the fifth terminal lead 181) with a conductive bonding material. The conductive member 41B is bonded to the obverse surface electrode 222 (the second chip 22) and the covered portion 172A (the sixth terminal lead 172) with a conductive bonding material. The conductive member 42B is bonded to the obverse surface electrode 224 (the second chip 22) and the covered portion 182A (the seventh terminal lead 182) with a conductive bonding material.

The first insulating member 61, the second insulating member 62, and the third insulating member 63 contain, for example, the same resin material as the sealing resin 50. Unlike this example, the first insulating member 61, the second insulating member 62, and the third insulating member 63 may contain other insulating materials.

As with the insulating member 60 of the semiconductor device A10, the first insulating member 61 is formed to ride over the two conductive members 31 and 32 and fixes the conductive members to each other.

The second insulating member 62 is in contact with the two conductive members 41A and 42A and fix the conductive members to each other. A portion of the conductive member 41A and a portion of the conductive member 42A are covered with the second insulating member 62 in the thickness direction z. The shape in plan view of the second insulating member 62 is not limited in any way, and is rectangular in the illustrated example.

The third insulating member 63 is in contact with the two conductive members 41B and 42B and fix the conductive members. A portion of the conductive member 41B and a portion of the conductive member 42B are covered with the third insulating member 63 in the thickness direction z. The shape in plan view of the third insulating member 63 is not limited in any way, and is rectangular in the illustrated example.

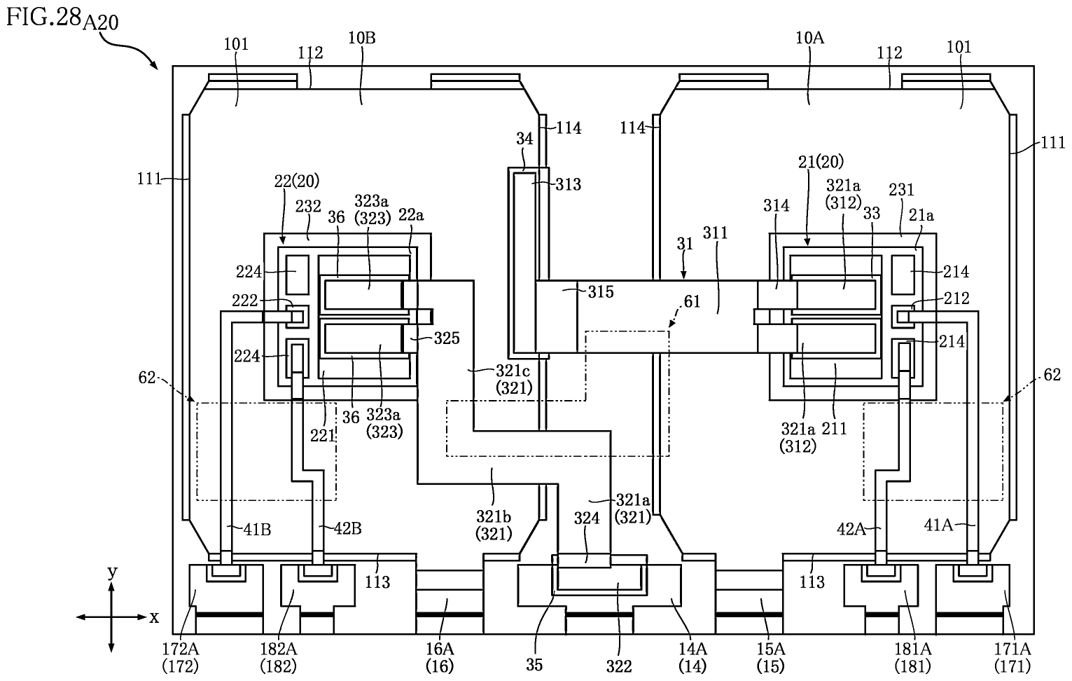

In the semiconductor device A20, the first bond portion 312 of the conductive member 31 includes two band-shaped portions 312a, as shown in FIGS. 27 and 28. As shown in FIGS. 27 and 28, the two band-shaped portions 312a are spaced apart from each other in the second direction y. Each of the band-shaped portions 312a is elongated in the first direction x. The two band-shaped portions 312a are arranged parallel (or generally parallel) to each other in plan view. Unlike this example, the first bond portion 312 may not be separated into two band-shaped portions 312a.

In the semiconductor device A20, the fourth bond portion 323 of the conductive member 32 includes two band-shaped portions 323a, as shown in FIGS. 27 and 28. As shown in FIGS. 27 and 28, the two band-shaped portions 323a are spaced apart from each other in the second direction y. Each of the band-shaped portions 323a is elongated in the first direction x. The two band-shaped portions 323a are arranged parallel (or generally parallel) to each other in plan view. Unlike this example, the fourth bond portion 323 may not be separated into two band-shaped portions 323a.

In the semiconductor device A20, the two conductive members 41A and 42A are bonded to the first chip 21 (the obverse surface electrode 212 and the obverse surface electrode 214) and the covered portions 171A and 181A while being fixed by the second insulating member 62. The two conductive members 41A and 42A are formed from the same lead frame and fixed together by the second insulating member 62 in the state of the lead frame. Likewise, the two conductive members 41B and 42B are bonded to the second chip 22 (the obverse surface electrode 222 and the obverse surface electrode 224) and the covered portions 172A and 182A while being fixed together by the third insulating member 63. The two conductive members 41B and 42B are formed from the same lead frame and fixed together by the third insulating member 63 in the state of the lead frame.

In the semiconductor device A20, the two conductive members 31 and 32 are fixed together by the first insulating member 61. Since the two conductive members 31 and 32 can be collectively placed in this way, the semiconductor device A20 can improve the production efficiency. Moreover, as with the semiconductor device A10, the semiconductor device A20 can suppress the deviation in the relative positional relationship between the two conductive members 31 and 32, and hence, prevent these members from coming into contact with each other. Furthermore, as with the semiconductor device A10, the semiconductor device A20 can increase the mutual inductance generated by the current flowing in the conductive member 31 and the current flowing in the conductive member 32, and hence, reduce the parasitic inductance. The semiconductor device A20 has a configuration in common with the semiconductor device A10, thereby achieving the same effect as the semiconductor device A10.

In the semiconductor device A20, the two conductive members 41A and 42A are fixed together by the second insulating member 62. With such a configuration, during the manufacturing process of the semiconductor device A20, the two conductive members 41A and 42A can be bonded to the semiconductor circuit section 20 while being fixed together by the second insulating member 62. Since the two conductive members 41A and 42A can be collectively placed in this way, the semiconductor device A20 can improve the production efficiency. In addition, since the two conductive members 41A and 42A are disposed while being fixed by the second insulating member 62, the deviation in the relative positional relationship between the conductive members can be suppressed. Thus, the semiconductor device A20 can prevent the two conductive members 41A and 42A from coming into contact with each other.

In the semiconductor device A20, the two conductive members 41B and 42B are fixed together by the third insulating member 63. With such a configuration, during the manufacturing process of the semiconductor device A20, the two conductive members 41B and 42B can be bonded to the semiconductor circuit section 20 while being fixed together by the third insulating member 63. Since the two conductive members 41B and 42B can be collectively placed in this way, the semiconductor device A20 can improve the production efficiency. In addition, since the two conductive members 41B and 42B are disposed while being fixed by the third insulating member 63, the deviation in the relative positional relationship between the conductive members can be suppressed. Thus, the semiconductor device A20 can prevent the two conductive members 41B and 42B from coming into contact with each other.

In the second embodiment, the semiconductor device A20 includes the first insulating member 61, the second insulating member 62, and the third insulating member 63. Unlike this example, the semiconductor device A20 may include one or two of the first insulating member 61, the second insulating member 62, and the third insulating member 63. For example, the semiconductor device A20 may include only the second insulating member 62. In such a case, the conductive member 41A is an example of the “first conductive member” in the claims, and the conductive member 42A is an example of the “second conductive member” in the claims.

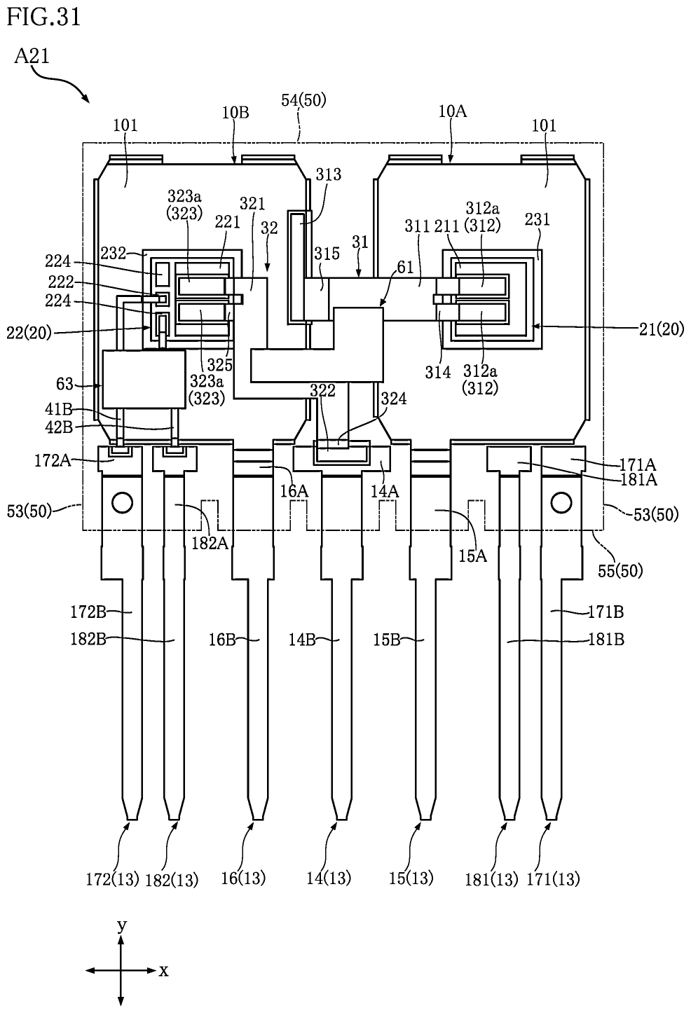

FIG. 31 shows a semiconductor device A21 according to a first variation of the second embodiment. In the semiconductor device A21, as with the semiconductor device A11, the first chip 21 a diode rather than a transistor. As shown in FIG. 31, unlike the semiconductor device A20, the semiconductor device A21 does not include either of the two conductive members 41A and 42A, and also does not include the second insulating member 62.

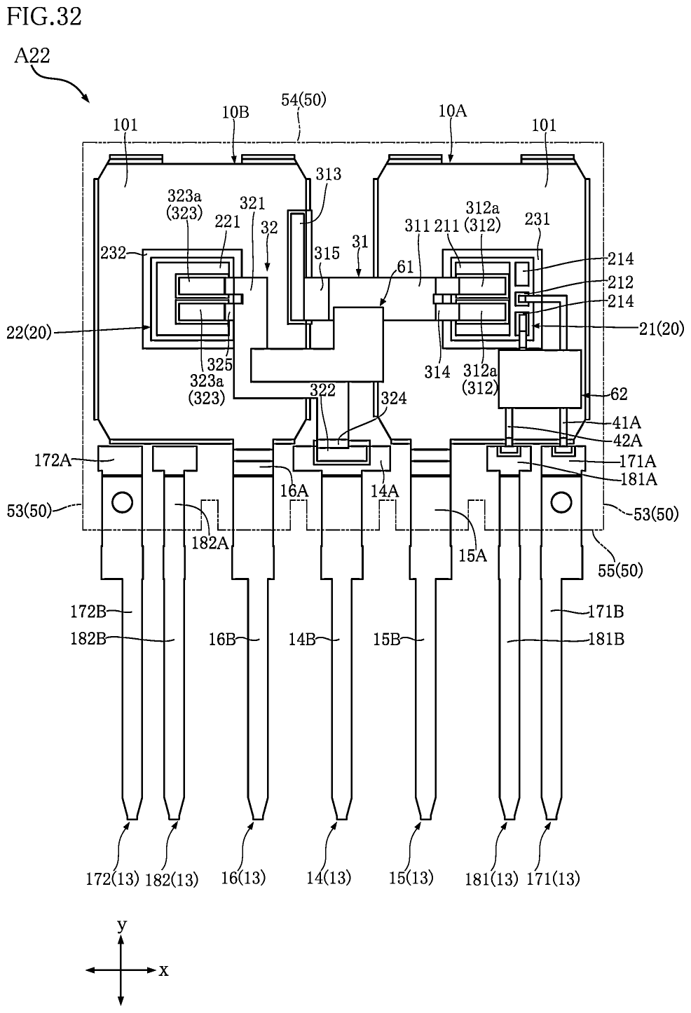

FIG. 32 shows a semiconductor device A22 according to a second variation of the second embodiment. In the semiconductor device A22, as with the semiconductor device A12, the second chip 22 a diode rather than a transistor. As shown in FIG. 32, unlike the semiconductor device A20, the semiconductor device A22 does not include either of the two conductive members 41B and 42B, and also does not include the third insulating member 63.

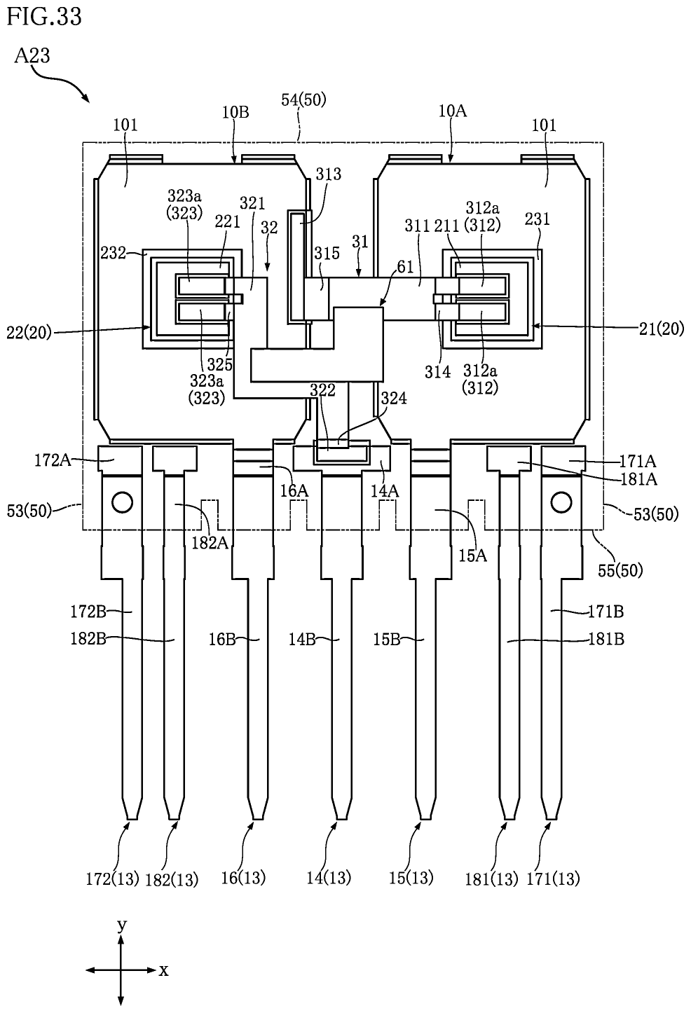

FIG. 33 shows a semiconductor device A23 according to a third variation of the second embodiment. In the semiconductor device A23, as with the semiconductor device A13, each of the first chip 21 and the second chip 22 is a diode rather than a transistor. As shown in FIG. 33, unlike the semiconductor device A20, the semiconductor device A23 does not include any of the conductive members 41A, 42A, 41B, and 42B, and also does not include either of the second insulating member 62 and the third insulating member 63.

In the semiconductor devices A21 to A23 according to the variations of the second embodiment, as with the semiconductor device A20, the two conductive members 31 and 32 are fixed together by the first insulating member 61. Thus, in the semiconductor devices A21 to A23, the two conductive members 31 and 32 can be collectively disposed as with the semiconductor device A20, so that the production efficiency can be improved. The semiconductor devices A21 to A23 have a configuration in common with the semiconductor device A20, thereby achieving the same effect as the semiconductor device A20. For example, the semiconductor devices A21 to A23 can prevent the two conductive members 31 and 32 from coming into contact with each other. Furthermore, the semiconductor devices A21 to A23 can increase the mutual inductance generated by the current flowing in the conductive member 31 and the current flowing in the conductive member 32, and hence, reduce the parasitic inductance.

The semiconductor devices according to other variations will be described below with reference to the drawings as appropriate. Unless otherwise specified, the variations described below can be applied to each of the semiconductor devices A10 to A13 and A20 to A23 shown in the first and the second embodiments (including variations of these).

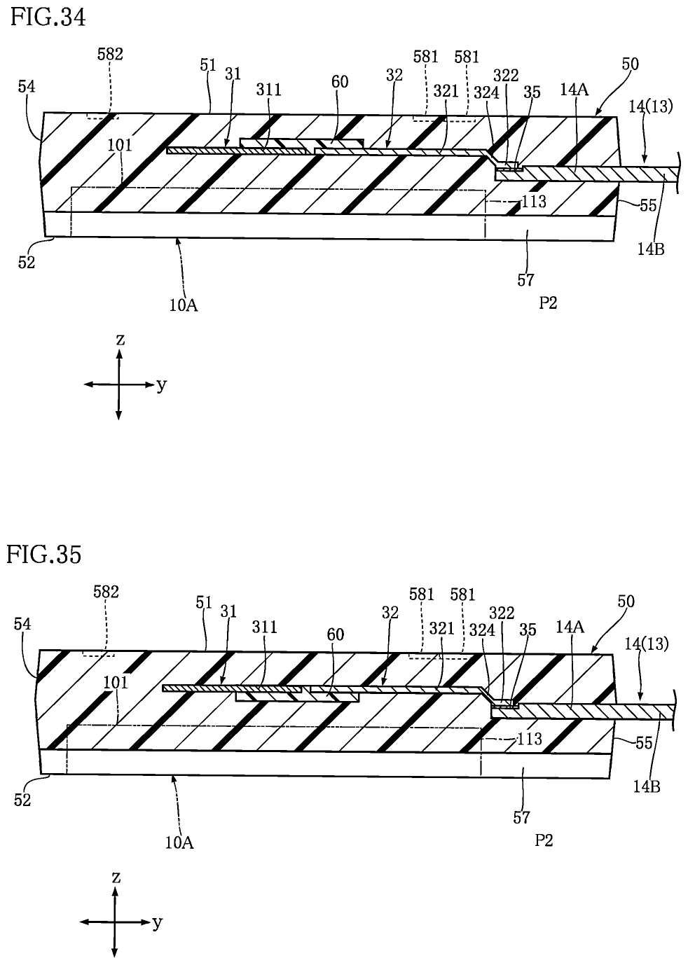

In a configuration different from the semiconductor devices A10 to A13 and A20 to A23 according to the first and the second embodiments, the insulating member 60 (the first insulating member 61) may not embed therein the conductive member 31 and the conductive member 32 in the thickness direction z. For example, FIG. 34 shows an example configuration in which the insulating member 60 is not formed on the lower side in the thickness direction z of the conductive members 31 and 32 in the semiconductor device A10. Also, FIG. 35 shows an example configuration in which the insulating member 60 is not formed on the upper side in the thickness direction z of the conductive members 31 and 32 in the semiconductor device A10. In these variations as well, the two conductive members 31 and 32 can be collectively disposed while being fixed together by the insulating member 60 (the first insulating member 61). However, the two conductive members 31 and 32 can be fixed more firmly when the insulating member 60 (the first insulating member 61) is configured to embed the conductive member 31 and the conductive member 32 in the thickness direction z. In addition, these variations can be applied not only to the insulating member 60 (the first insulating member 61) but also to the second insulating member 62 and the third insulating member 63.

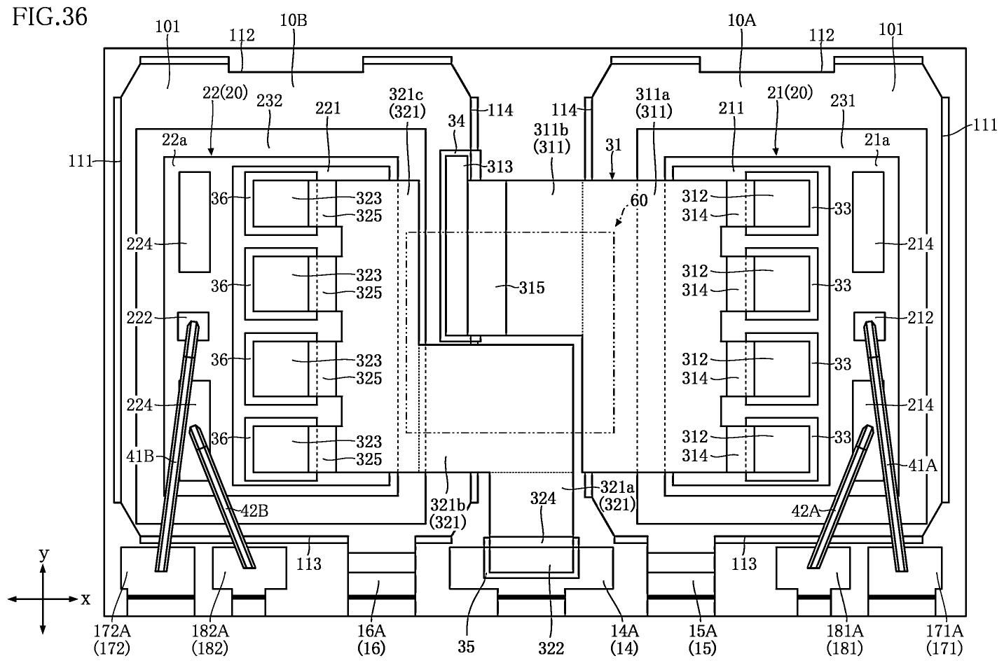

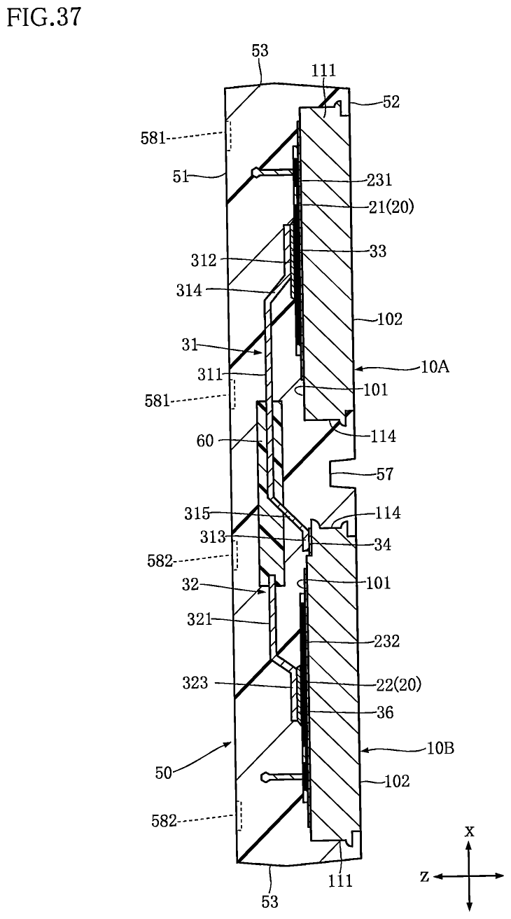

In a configuration different from the semiconductor devices A10 to A13 and A20 to A23 according to the first and the second embodiments, the insulating member 60 (the first insulating member 61) may be in contact with one of the first connecting portion 314, the second connecting portion 315, the third connecting portion 324, and the fourth connecting portion 325. For example, FIGS. 36 and 37 shows an example configuration in which the insulating member 60 is in contact with the second connecting portion 315 in the semiconductor device A10. In such a variations as well, the two conductive members 31 and 32 can be collectively disposed while being fixed together by the insulating member 60 (the first insulating member 61). In addition, since the formation area of the insulation member 60 is larger in this variation, the two conductive members 31 and 32 can be more firmly fixed by the insulation member 60.

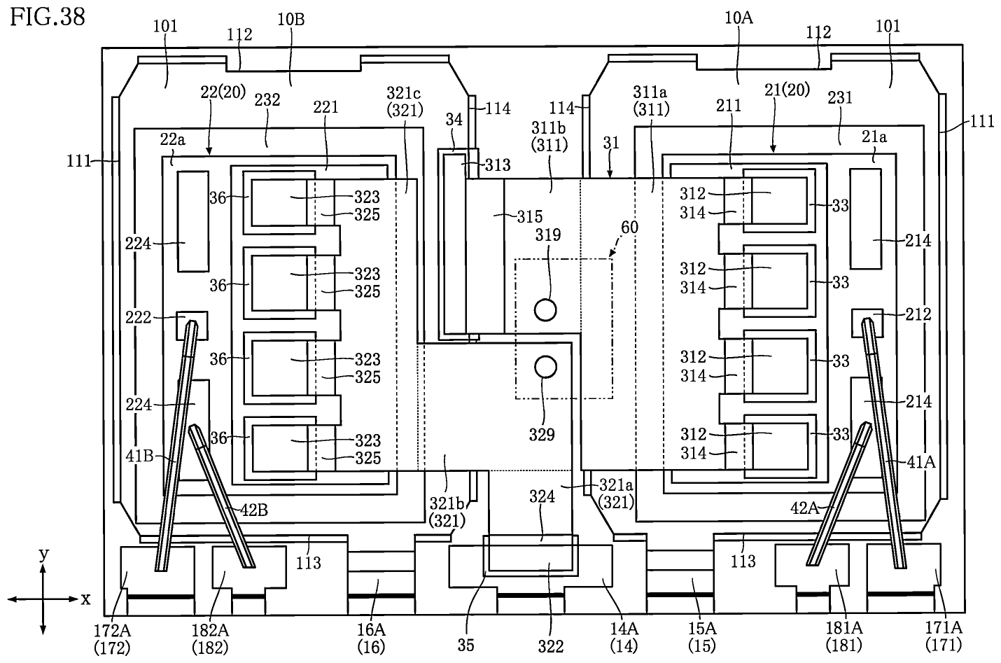

In a configuration different from the semiconductor devices A10 to A13 and A20 to A23 according to the first and the second embodiments, the conductive member 31 may be formed with a through-hole at a portion covered with the insulating member 60. Likewise, the conductive member 32 may be formed with a through-hole at a portion covered with the insulating member 60. For example, FIG. 38 shows an example configuration in which the conductive member 31 is formed with a through-hole 319 whereas the conductive member 32 is formed with a through- hole 329 in the semiconductor device A10. The through-hole 319 is formed at a portion of the first main body 311 of the conductive member 31 that is covered with the insulating member 60. The through-hole 319 penetrates the first main body 311 in the thickness direction z. The through-hole 329 is formed at a portion of the second main body 321 of the conductive member 32 that is covered with the insulating member 60. The through-hole 329 penetrates the second main body 321 in the thickness direction z. The through-holes 319 and 329 are filled with the insulating member 60. In such a variations as well, the two conductive members 31 and 32 can be collectively disposed while being fixed together by the insulating member 60. The present variation further provides the following effects. First, during the formation (molding) of the insulating member 60, the resin material flows from the upper side to the lower side of the conductive member 31 in the thickness direction z through the through-holes 319 and 329, which suppresses formation of voids in the insulating member 60. Second, because the insulating member 60 is formed in the through-holes 319 and 329, separation of the insulating member 60 from the conductive members 31 and 32 is prevented.

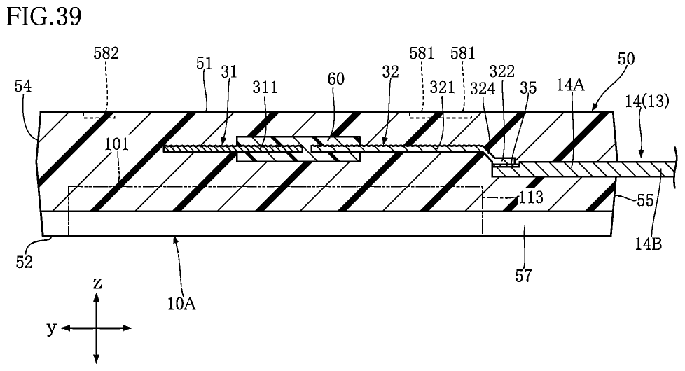

In a configuration different from the semiconductor devices A10 to A13 and A20 to A23 according to the first and the second embodiments, the conductive member 31 may have irregularities on the surface that is in contact with the insulating member 60. Likewise, the conductive member 32 may have irregularities on the surface that is in contact with the insulating member 60. For example, FIG. 39 shows an example configuration in which the upper surface (the surface facing upward in the thickness direction z) of the first main body 311 of the conductive member 31 and the upper surface (the surface facing upward in the thickness direction z) of the second main body 321 of the conductive member 32 are rough surfaces (with minute irregularities) in the semiconductor device A10. In such a variations as well, the two conductive members 31 and 32 can be collectively disposed while being fixed together by the insulating member 60. Furthermore, in the present variation, the anchoring effect by the irregularities of the two conductive members 31 and 32 prevents the insulating member 60 from separating from the conductive members 31 and 32. Although the upper surfaces of the first main body 311 and the second main body 321 are rough surfaces in the illustrated example, the lower surfaces may also be rough surfaces, or only the regions in contact with the insulating member 60 may have rough surfaces.

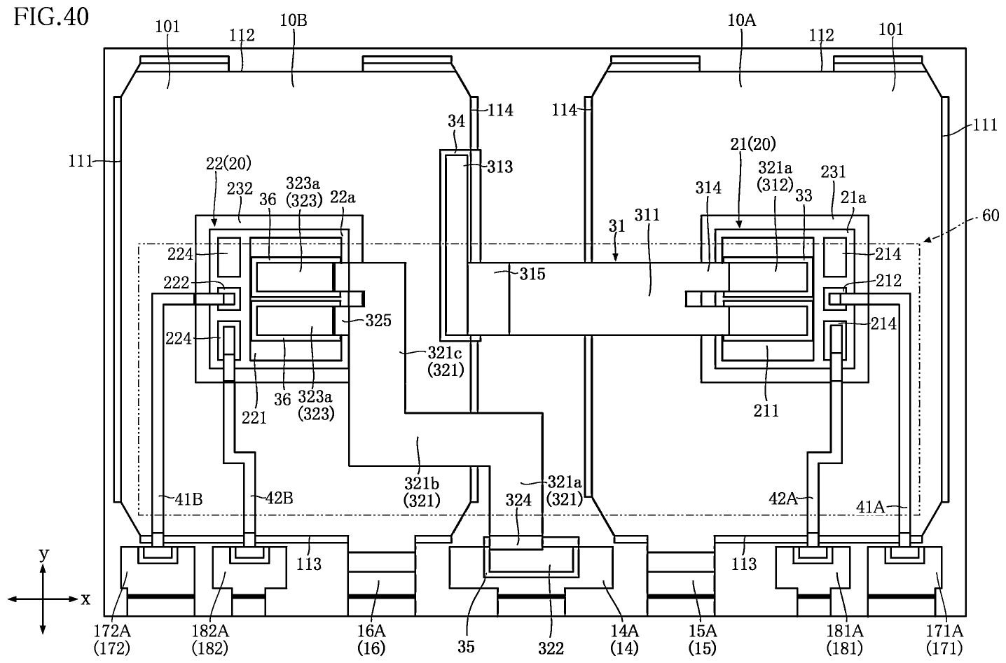

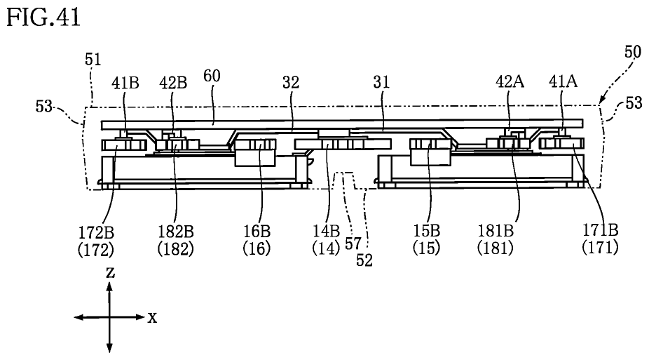

In a configuration different from the semiconductor devices A10 to A13 and A20 to A23 according to the first and the second embodiments, the insulating member 60 may be an insulating adhesive sheet rather than a molded resin material. For example, FIGS. 40 and 41 show an example configuration in which the insulating member 60 is an insulating adhesive sheet in the semiconductor device A20. In the semiconductor device shown in FIGS. 40 and 41, the upper surfaces of the conductive member 31, the conductive member 32, the conductive member 41A, the conductive member 42A, the conductive member 41B, and the conductive member 42B are located at the same (or approximately the same) height in the thickness direction z. The insulating member 60 is in contact with and adheres to a portion of the upper surface of each of the two conductive members 31 and 32 and conductive members 41A, 42A, 41B, and 42B. In such a variations as well, the two conductive members 31 and 32 can be collectively disposed while being fixed together by the insulating member 60. Furthermore, in the present variation, the conductive members 41A, 42A, 41B, and 42B can also be collectively disposed by using the insulating member 60.

In a configuration different from the semiconductor devices A10 to A13 and A20 to A23 according to the first and the second embodiments, the semiconductor circuit section 20 may include a plurality of first chips 21. In such a variation, the plurality of first chips 21 may all be transistors or diodes, or may include a transistor and a diode (e.g., connected in reverse parallel to the transistor). Likewise, the semiconductor circuit section 20 may include a plurality of second chips 22. In such a variation, the plurality of second chips 22 may all be transistors or diodes, or may include a transistor and a diode (e.g., connected in reverse parallel to the transistor).

The package structure of the semiconductor device of the present disclosure is not limited to that illustrated in the first through the third embodiments (including variations thereof). For example, the semiconductor device of the present disclosure can also be applied to other TO (Transistor Outline) packages. Specifically, the semiconductor devices A10 to A13 and A20 to A23 of the first and the second embodiments are an extension of the package structure called TO-247, but they can also be an extension of other package structures such as TO-220, TO-252, or TO263. In other words, the semiconductor device of the present disclosure enables the packaging of a plurality of semiconductor elements (the first chip 21 and the second chip 22) with a single sealing resin 50 while maintaining an appearance similar to that of conventional TO packages.

The semiconductor device and the method for manufacturing the semiconductor device according to the present disclosure is not limited to the above-described embodiments. Various modifications in design may be made freely in the specific structure of each part of the semiconductor device according to the present disclosure and in the specific process in each step of the semiconductor device manufacturing method according to the present disclosure. For example, the semiconductor device and the semiconductor device manufacturing method according to the present disclosure include embodiments described in the following clauses.

### Clause 1.

A semiconductor device comprising:
a semiconductor circuit section;
a first conductive member electrically conducting to the semiconductor circuit section;
a second conductive member electrically conducting to the semiconductor circuit section;
an insulating member in contact with the first conductive member and the second conductive member; and
a sealing resin covering the semiconductor circuit section, the first conductive member, the second conductive member, and a portion of the insulating member,
wherein the first conductive member and the second conductive member are fixed together by the insulating member.

### Clause 2.

The semiconductor device according to clause 1, wherein the semiconductor circuit section includes a first chip and a second chip,
the first conductive member is bonded to the first chip, and
the second conductive member is bonded to the second chip.

### Clause 3.

The semiconductor device according to clause 2, wherein the first chip and the second chip are electrically connected in series, and
the semiconductor circuit section forms a half-bridge circuit.

### Clause 4.

The semiconductor device according to clause 3, comprising: a first mount portion on which the first chip is mounted;
a second mount portion on which the second chip is mounted; and
a first terminal lead spaced apart from the first mount portion and the second mount portion.

### Clause 5.

The semiconductor device according to clause 4, wherein the first chip includes a first obverse surface facing one side in a thickness direction of the sealing resin, a first reverse surface facing another side in the thickness direction, a first obverse surface electrode formed on the first obverse surface, and a first reverse surface electrode formed on the first reverse surface,
the first reverse surface electrode faces the first mount portion and electrically conducts to the first mount portion,
the second chip includes a second obverse surface facing said one side in the thickness direction, a second reverse surface facing said another side in the thickness direction, a second obverse surface electrode formed on the second obverse surface, and a second reverse surface electrode formed on the second reverse surface, and
the second reverse surface electrode faces the second mount portion and electrically conducts to the second mount portion.

### Clause 6.

The semiconductor device according to clause 5, wherein the first conductive member electrically connects the first obverse surface electrode and the second mount portion, and
the second conductive member electrically connects the second obverse surface electrode and the first terminal lead.

### Clause 7.

The semiconductor device according to clause 6, wherein the first mount portion is located on one side in a first direction orthogonal to the thickness direction with respect to the second mount portion.

### Clause 8.

The semiconductor device according to clause 7, further comprising: a second terminal lead extending from the first mount portion in a second direction orthogonal to the thickness direction and the first direction; and
a third terminal lead extending from the second mount portion in the second direction,
wherein the first terminal lead, the second terminal lead, and the third terminal lead are arranged in the first direction.

### Clause 9.

The semiconductor device according to clause 8, wherein the first terminal lead is located between the second terminal lead and the third terminal lead in the first direction.

### Clause 10.

The semiconductor device according to clause 9, further comprising:
a fourth terminal lead;
a fifth terminal lead;
a third conductive member electrically connecting the first chip and the fourth terminal lead; and
a fourth conductive member electrically connecting the first chip and the fifth terminal lead,
wherein the fourth terminal lead and the fifth terminal lead are located on said one side in the first direction form the second terminal lead and next to each other in the first direction.

### Clause 11.

The semiconductor device according to clause 10, further comprising a second insulating member, wherein
the insulating member in contact with the first conductive member and the second conductive member is a first insulating member,
each of the third conductive member and the fourth conductive member is a plate member, and
the second insulating member fixes the third conductive member and the fourth conductive member to each other.

### Clause 12.

The semiconductor device according to clause 10 or 11, further comprising:
a sixth terminal lead;
a seventh terminal lead;
a fifth conductive member electrically connecting the second chip and the sixth terminal lead; and
a sixth conductive member electrically connecting the second chip and the seventh terminal lead,
wherein the sixth terminal lead and the seventh terminal lead are located on another side in the first direction form the third terminal lead and next to each other in the first direction.

### Clause 13.

The semiconductor device according to clause 12, further comprising a third insulating member, wherein
each of the fifth conductive member and the sixth conductive member is a plate member, and
the third insulating member fixes the fifth conductive member and the sixth conductive member to each other.

### Clause 14.

The semiconductor device according to any one of clauses 2 to 13, wherein the first chip is either a transistor or a diode, and
the second chip is either a transistor or a diode.

### Clause 15.

The semiconductor device according to any one of clauses 1 to 14, wherein the insulating member is formed in an area where the first conductive member and the second conductive member are close to each other as viewed in the thickness direction of the sealing resin.

### Clause 16.

The semiconductor device according to any one of clauses 1 to 15, wherein the insulating member contains a same resin material as the sealing resin.

### Clause 17.

The semiconductor device according to any of clauses 1 to 16, wherein a portion of the first conductive member and a portion of the second conductive member are embedded in the insulating member in the thickness direction.

### Clause 18.

A method for manufacturing a semiconductor device, the method comprising the steps of:
preparing a lead frame including a first conductive member and a second conductive member;
fixing the first conductive member and the second conductive member to each other by an insulating member, with the lead frame including the first conductive member and the second conductive member;
bonding the first conductive member and the second conductive member to a semiconductor circuit section with the first conductive member and the second conductive member being fixed together by the insulating member, and
forming a sealing resin covering the first conductive member, the second conductive member, and the semiconductor circuit section.

REFERENCE NUMERALS

A10~A13, A20~A23: Semiconductor device
10A: First mount portion
10B: Second mount portion
101: Obverse surface
102: Reverse surface
103: First seating surface
104: First standing surface
111: First end surface
112: Second end surface
113: Third end surface
114: Fourth end surface
13: Terminal lead
14: First terminal lead
14A: Covered portion
14B: Exposed portion
14C: Second seating surface
14D: Second standing surface
15: Second terminal lead
15A: Covered portion
15B: Exposed portion
16: Third terminal lead
16A: Covered portion
16B: Exposed portion
171: Fourth terminal lead
171A: Covered portion
171B: Exposed portion
172: Sixth terminal lead
172A: Covered portion
172B: Exposed portion
181: Fifth terminal lead
181A: Covered portion
181B: Exposed portion
182: Seventh terminal lead
182A: Covered portion
182B: Exposed portion
20: Semiconductor circuit section
21: First chip
21a: First obverse surface
21b: First reverse surface
211: First obverse surface electrode
212, 214: Obverse surface electrode
213: First reverse surface electrode
22: Second chip
22a: Second obverse surface
22b: Second reverse surface
221: Second obverse surface electrode
222, 224: Obverse surface electrode
223: Second reverse surface electrode
231, 232: Die bonding layer
30: Lead frame
301: Frame portion
302: Suspending portion
31: Conductive member
311: First main body
311a, 311b: Section
312: First bond portion
312a: Band-shaped portion
313: Second bond portion
314: First connecting portion
315: Second connecting portion
319: Through-hole
32: Conductive member
321: Second main body
321a, 321b, 321c: Section
322: Third bond portion
323: Fourth bond portion
323a: Band-shaped portion
324: Third connecting portion
325: Fourth connecting portion
329: Through-hole
33: First bonding layer
34: Second bonding layer
35: Third bonding layer
36: Fourth bonding layer
41A, 41B, 42A, 42B: Conductive member
50: Sealing resin
51: Resin obverse surface
52: Resin reverse surface
53: First side surface
54: Second side surface
55: Third side surface
56: Recess
57: Groove
581, 582: Recess
60: Insulating member
61: First insulating member
62: Second insulating member
63: Third insulating member

1. A semiconductor device comprising:
a semiconductor circuit section;
a first conductive member electrically conducting to the semiconductor circuit section;
a second conductive member electrically conducting to the semiconductor circuit section;
an insulating member in contact with the first conductive member and the second conductive member; and
a sealing resin covering the semiconductor circuit section, the first conductive member, the second conductive member, and a portion of the insulating member,
wherein the first conductive member and the second conductive member are fixed together by the insulating member.

2. The semiconductor device according to claim 1, wherein the semiconductor circuit section includes a first chip and a second chip,
the first conductive member is bonded to the first chip, and
the second conductive member is bonded to the second chip.

3. The semiconductor device according to claim 2, wherein the first chip and the second chip are electrically connected in series, and
the semiconductor circuit section forms a half-bridge circuit.

4. The semiconductor device according to claim 3, comprising: a first mount portion on which the first chip is mounted;
a second mount portion on which the second chip is mounted; and
a first terminal lead spaced apart from the first mount portion and the second mount portion.

5. The semiconductor device according to claim 4, wherein the first chip includes a first obverse surface facing one side in a thickness direction of the sealing resin, a first reverse surface facing another side in the thickness direction, a first obverse surface electrode formed on the first obverse surface, and a first reverse surface electrode formed on the first reverse surface,
the first reverse surface electrode faces the first mount portion and electrically conducts to the first mount portion,
the second chip includes a second obverse surface facing said one side in the thickness direction, a second reverse surface facing said another side in the thickness direction, a second obverse surface electrode formed on the second obverse surface, and a second reverse surface electrode formed on the second reverse surface, and
the second reverse surface electrode faces the second mount portion and electrically conducts to the second mount portion.

6. The semiconductor device according to claim 5, wherein the first conductive member electrically connects the first obverse surface electrode and the second mount portion, and
the second conductive member electrically connects the second obverse surface electrode and the first terminal lead.

7. The semiconductor device according to claim 6, wherein the first mount portion is located on one side in a first direction orthogonal to the thickness direction with respect to the second mount portion.

8. The semiconductor device according to claim 7, further comprising: a second terminal lead extending from the first mount portion in a second direction orthogonal to the thickness direction and the first direction; and
a third terminal lead extending from the second mount portion in the second direction,
wherein the first terminal lead, the second terminal lead, and the third terminal lead are arranged in the first direction.

9. The semiconductor device according to claim 8, wherein the first terminal lead is located between the second terminal lead and the third terminal lead in the first direction.

10. The semiconductor device according to claim 9, further comprising:
a fourth terminal lead;
a fifth terminal lead;
a third conductive member electrically connecting the first chip and the fourth terminal lead; and
a fourth conductive member electrically connecting the first chip and the fifth terminal lead,
wherein the fourth terminal lead and the fifth terminal lead are located on said one side in the first direction form the second terminal lead and next to each other in the first direction.

11. The semiconductor device according to claim 10, further comprising a second insulating member, wherein
the insulating member in contact with the first conductive member and the second conductive member is a first insulating member,
each of the third conductive member and the fourth conductive member is a plate member, and
the second insulating member fixes the third conductive member and the fourth conductive member to each other.

12. The semiconductor device according to claim 10, further comprising:
a sixth terminal lead;
a seventh terminal lead;
a fifth conductive member electrically connecting the second chip and the sixth terminal lead; and
a sixth conductive member electrically connecting the second chip and the seventh terminal lead,
wherein the sixth terminal lead and the seventh terminal lead are located on another side in the first direction form the third terminal lead and next to each other in the first direction.

13. The semiconductor device according to claim 12, further comprising a third insulating member, wherein
each of the fifth conductive member and the sixth conductive member is a plate member, and
the third insulating member fixes the fifth conductive member and the sixth conductive member to each other.

14. The semiconductor device according to claim 2, wherein the first chip is either a transistor or a diode, and
the second chip is either a transistor or a diode.

15. The semiconductor device according to claim 1, wherein the insulating member is formed in an area where the first conductive member and the second conductive member are close to each other as viewed in the thickness direction of the sealing resin.

16. The semiconductor device according to claim 1, wherein the insulating member contains a same resin material as the sealing resin.

17. The semiconductor device according to claim 1, wherein a portion of the first conductive member and a portion of the second conductive member are embedded in the insulating member in the thickness direction.

18. A method for manufacturing a semiconductor device, the method comprising the steps of:
preparing a lead frame including a first conductive member and a second conductive member;
fixing the first conductive member and the second conductive member to each other by an insulating member, with the lead frame including the first conductive member and the second conductive member;
bonding the first conductive member and the second conductive member to a semiconductor circuit section with the first conductive member and the second conductive member being fixed together by the insulating member, and
forming a sealing resin covering the first conductive member, the second conductive member, and the semiconductor circuit section.
